(19) United States
(12) Patent Application Publication
(10) Pub. No.: US 2026/0366103 A1
(43) Pub. Date: Nov. 19, 2026

(54) ZIRCONIUM-RICH CR-ZR-N ALLOY COATING, COATED PRODUCT, USE IN HARD COATING, AND PREPARATION METHOD

(71) Applicant: VITALINK INDUSTRY (SHENZHEN) CO., LTD., Shenzhen, Guangdong (CN)

(72) Inventors: Yue DONG, Shenzhen (CN); Zhi TAN, Shenzhen (CN); Jiamin LIANG, Shenzhen (CN); Feng HUANG, Shenzhen (CN); Wei WANG, Shenzhen (CN)

(21) Appl. No.: 19/477,013

(22) PCT Filed: Feb. 1, 2024
(86) PCT No.: PCT/CN2024/075244

§ 371 Date: Oct. 20, 2025

(30) Foreign Application Priority Data
Jun. 21, 2023 (CN) 202310746573.8

(51) Int. Cl. C22C 16/00; C23C 14/16; C23C 14/34; C23C 14/54

(52) U.S. Cl. CPC C22C 16/00; C23C 14/16; C23C 14/3414; C23C 14/542

(57) ABSTRACT

A Zr-rich Cr—Zr—N alloy coating, a coated article, use, and a preparation method are provided. The zirconium-rich Cr—Zr—N alloy coating includes a Cr—Zr—N alloy material represented by a chemical formula of (CrₓZr_{y}N_{z})Mₐ, where M is a doping element, x, y, z, and a are each independently an atomic proportion, 15.0≤x≤53.8, 30.0≤y≤78.8, 6.2≤z≤35.5, and 0≤a/(x+y+z+a)≤0.05.

This application is an U.S. national phase application under 35 U.S.C. § 371 based upon international patent application No. PCT/CN2024/075244 filed on Feb. 1, 2024, which itself claims priority to Chinese patent application No. 2023107465738, filed on Jun. 21, 2023, entitled “ZIRCONIUM-RICH CR—ZR—N ALLOY COATING, COATED ARTICLE, USE IN HARD COATING AND PREPARATION METHOD”. The contents of the above identified applications are hereby incorporated by reference in their entireties.

### TECHNICAL FIELD

The present disclosure relates to the technical field of alloy coating, further to the technical field of zirconium-containing coating, and in particular to a Zr-rich Cr—Zr—N alloy coating, a coated article, use in the field of hard coating, and a preparation method.

### BACKGROUND

With the rapid development of modern science and technology, hard coatings have emerged in order to improve the surface performances of various materials and components. The hard coatings have high hardness and are playing an increasingly important role in fields such as 3C digital products, mechanical processing, mold manufacturing, geological drilling, textile industry, and aerospace.

Metal nitrides generally have characteristics such as high melting points and hardness, good thermal stability, and excellent oxidation resistance. Nitrides of transition metals such as titanium (Ti), chromium (Cr), vanadium (V), niobium (Nb), zirconium (Zr), hafnium (Hf) are commonly used as strengthening coatings on tool surfaces to increase hardness. Titanium nitride coatings (TiN coatings) and chromium nitride coatings (CrN coatings) are the most common, earliest studied, and widely used coatings. TiN coatings have advantages such as high hardness, good toughness, good chemical stability, and gorgeous color, and have been successfully applied in the tool industry and are once praised as “a revolution in tools”. In addition to being used as functional coatings, TiN coatings can be used as decorative coatings as well. Compared with TiN coatings, CrN coatings have lower friction coefficients, better high-temperature resistance and corrosion resistance, and higher sputtering yield, which are beneficial to industrial mass production. Moreover, CrN coatings have relatively low internal stress, resulting in hardness values lower than those of TiN coatings.

With the widespread application of coated products, coated substrates have entered the era of lightweight alloys, such as aluminum alloys. However, these lightweight alloy materials have relatively week corrosion resistance, which have led new requirements for the corrosion resistance of the hard coatings. The protective coatings on the surface of the substrates are required not only to possess high hardness, but also to possess excellent corrosion resistance. However, for conventional single-metal nitride coatings, due to the high internal stress of the coatings and the accompanying defects during a coating growth process, there is a problem that the coatings have high hardness but poor corrosion resistance. In view of this, the research and development of alloy nitride coatings have emerged timely.

However, it is usually difficult for existing alloy nitride coatings to meet the requirements of high hardness and high corrosion resistance at the same time.

### SUMMARY

According to various embodiments and examples of the present disclosure, an aspect of the present disclosure provides a Zr-rich Cr—Zr—N alloy coating. Other aspects of the present disclosure further provide a coated article, use in the field of hard coating, and a preparation method.

In a first aspect of the present disclosure, provided is a zirconium-rich Cr—Zr—N alloy coating, including a Cr—Zr—N alloy material, wherein the Cr—Zr—N alloy material is represented by a chemical formula of (CrₓZr_{y}N_{z})Mₐ, where M is a doping element, x, y, Z, and a are each independently an atomic proportion, 15.0≤x≤53.8, 30.0≤y≤78.8, 6.2≤z≤35.5, and 0≤a/(x+y+z+a)≤0.05.

In some embodiments, 64.5-y≤x≤93.8-y, and 15.0≤x≤1.93y-23.4.

In some embodiments, 15.0≤x≤53.8, 33.7≤y≤78.8, and 6.2≤z<28.0.4. In further embodiments, 72-y<x≤93.8-y, and 15.0≤x<2.5y-44.6.

In some embodiments, based on any suitable embodiments described above, a sum of x, y and z is 100.

In some embodiments, based on any suitable embodiments described above, the Cr—Zr—N alloy coating satisfies two features as follows:
an X-ray diffraction (XRD) pattern of the Cr—Zr—N alloy material or the Cr—Zr—N alloy coating has one or more peaks in a diffraction angle 2θ (°) range from 30° to 50°, and a full width at half maximum (FWHM) of at least one 2θ (°) diffraction peak in the range from 30° to 50° is greater than or equal to 2°; and
a radial intensity profile corresponding to a selected area electron diffraction (SAED) pattern of the Cr—Zr—N alloy material or the Cr—Zr—N alloy coating, with characteristic interatomic spacing as a horizontal axis and diffraction intensity as a vertical axis, has one or more diffraction peaks in a range from 2.0 Å to 3.0 Å, and a FWHM of at least one of the diffraction peaks in the range from 2.0 Å to 3.0 Å is greater than or equal to 0.21 Å.

In some embodiments, based on any suitable embodiments described above, a thickness of the Cr—Zr—N alloy coating is in a range from dₘᵢₙ to 6 μm, dₘᵢₙ being a value selected from 10 nm to 50 nm.

In some embodiments, dₘᵢₙ is 10 nm, 20 nm, 25 nm, 30 nm, 40 nm, or 50 nm.

In some embodiments, based on any suitable embodiments described above, the doping element is a non-metal element, a metal element, or a combination thereof;
the non-metal element includes O, C, B, Si, Ar, or any combination thereof; and
the metal element includes Ti, V, Nb, Mo, Hf, Ta, W, Ni, Mo, Fe, Ag, Au, Cu, Al, or any combination thereof.

In some embodiments, 0≤a/(x+y+z+a)≤0.02.

In a second aspect of the present disclosure, provided is a coated article, including a substrate and the Cr—Zr—N alloy coating as described in the first aspect, wherein the Cr—Zr—N alloy coating is located on at least one side of the substrate.

In some embodiments, a surface material of the substrate is an alloy, an elemental metal, or an inorganic non-metal material;
optionally, a material type of the alloy includes nickel base, iron base, tungsten base, titanium base, silicon base, aluminum base, copper base, cobalt base, zirconium base, zinc base, or any combination thereof;
optionally, the elemental metal is zinc, gold, platinum, zirconium, hafnium, niobium, tantalum, nickel, copper, aluminum, iron, silver, or chromium;
optionally, the inorganic non-metal material includes ceramic, glass, or any combination thereof.

In some embodiments, the surface material of the substrate is a light alloy or a stainless-steel;
optionally, the light alloy includes a titanium alloy, an aluminum alloy, a magnesium alloy, or any combination thereof.

In some embodiments, the coated article satisfies one or more of following features:
the Cr—Zr—N alloy coating is in direct contact with the substrate; alternatively, a transition layer is disposed between the Cr—Zr—N alloy coating and the substrate;
the Cr—Zr—N alloy coating forms a surface of the coated article; alternatively, a surface layer is disposed on a side of the Cr—Zr—N alloy coating away from the substrate, the surface layer being a single-layer structure or a multi-layer structure.

In a third aspect of the present disclosure, provided is use of the Cr—Zr—N alloy coating described in the first aspect of the present disclosure as at least a part of a hard coating, or use of the coated article described in the second aspect of the present disclosure in preparation of a product having a hard coating.

In some embodiments, the hard coating is further a corrosion-resistant coating.

In a fourth aspect of the present disclosure, provided is a method for preparing a Cr—Zr—N alloy coating, including a step of depositing composition elements of the Cr—Zr—N alloy coating onto at least a portion of a surface of a substrate according to a preset atomic ratio of the composition elements by vapor deposition, thereby forming the Cr—Zr—N alloy coating described in the first aspect of the present disclosure.

In some embodiments, the Cr—Zr—N alloy coating is formed by a method including a step of: under a condition of introducing a mixed gas containing argon gas and a nitrogen-containing gas, sputtering a target including chromium, zirconium, or a combination thereof to deposit the composition elements of the Cr—Zr—N alloy coating on at least a portion of a surface of a substrate, thereby forming the Cr—Zr—N alloy coating.

In some embodiments, the method satisfies one or more following features:
the sputtering deposition is performed at a temperature in a range from 30°C to 330 °C;
a total gas-pressure of the mixed gas containing argon gas and the nitrogen-containing gas is in a range from 0.3 Pa to 1.2 Pa;
the target includes a chromium target, and a power density for the chromium target is in a range from 1.3 W/cm² to 6.7 W/cm²;
the target includes a zirconium target, and a power density for the zirconium target is in a range from 0.8 W/cm² to 7.9 W/cm²;
the target includes an alloy target, the alloy target includes at least two metal elements of the Cr—Zr—N alloy coating; optionally, the target includes a chromium-zirconium-based alloy target, and a power density for the chromium-zirconium-based alloy target is in a range from 4 W/cm² to 6 W/cm²;
a bias voltage applied to the substrate is in a range from −150 V to −20 V;
the sputtering deposition is performed for 10 min to 150 min;
the nitrogen-containing gas is nitrogen gas, and a flow rate of the nitrogen gas is in a range from 8 standard cubic centimeter per minute (sccm) to 52 sccm; and
the nitrogen-containing gas is nitrogen gas, and a flow rate ratio of argon gas to nitrogen gas in the mixed gas is in a range from 2:1 to 6:1.

In a fifth aspect of the present disclosure, provided is a Cr—Zr—N alloy material, where the Cr—Zr—N alloy material is as defined in the first aspect of the present disclosure.

Details of one or more embodiments of the present disclosure are set forth in the accompanying drawings and description below. Other features, objects, and advantages of the present disclosure will become apparent from the description, drawings, and claims.

### BRIEF DESCRIPTION OF THE DRAWINGS

In order to more clearly illustrate the technical solutions in the embodiments or examples of the present disclosure, and to more comprehensively understand the present disclosure and beneficial effects thereof, the drawings used in the description of the embodiments or examples will be briefly introduced below. Apparently, the drawings described in the following are merely some embodiments of the present disclosure, and for those skilled in the art, other drawings can be obtained according to these drawings without any creative effort. It should also be noted that the accompanying drawings are drawn in a simplified form and are only used to conveniently and clearly illustrate the present disclosure. Various sizes of each component shown in the accompanying drawings are arbitrary, and may be precise or not drawn to the actual scale. For example, in order to make the drawings clearer, the sizes of components are appropriately exaggerated in some parts of the accompanying drawings. Unless otherwise specified, components in the drawings are not drawn to scale. The present disclosure does not limit each size of each component.

In the present disclosure, a same reference sign in the following description represents a same part.

FIG. 1 is a schematic structural view of a coated article including an exemplary zirconium-rich Cr—Zr—N alloy coating according to an embodiment of the present disclosure, including a substrate and an exemplary Cr—Zr—N alloy coating according to the present disclosure.

FIGS. 2A to 2C are schematic structural views of several coated articles according to several embodiments of the present disclosure: (FIG. 2A) including a substrate, a transition layer, and an exemplary Cr—Zr—N alloy coating of the present disclosure; (FIG. 2B) including a substrate, a transition layer, an exemplary Cr—Zr—N alloy coating of the present disclosure, and a surface layer; (FIG. 2C) including a substrate, an exemplary Cr—Zr—N alloy coating of the present disclosure, and a surface layer.

FIG. 3 is a schematic view of a device for preparing a Cr—Zr—N alloy coating of the present disclosure according to an embodiment of the present disclosure.

FIG. 4 shows a scanning electron microscopic (SEM) image of a cross-section of a Cr_{53.8}Zr_{40.0}N_{6.2} alloy coating prepared in Example 1 of the present disclosure.

FIGS. 5A to 5C show an X-ray diffraction (XRD) pattern (FIG. 5A), a selected area electron diffraction (SAED) pattern (FIG. 5B), and a radial intensity profile (FIG. 5C) of a Cr_{53.8}Zr_{40.0}N_{6.2} alloy coating prepared in Example 1 of the present disclosure,

FIG. 6 shows an SEM image of a cross-section of a Cr_{34.5}Zr_{30.0}N_{35.5} alloy coating prepared in Example 2 of the present disclosure.

FIGS. 7A to 7C show an XRD pattern (FIG. 7A), an SAED pattern (FIG. 7B), and a radial intensity profile (FIG. 7C) of a Cr_{34.5}Zr_{30.0}N_{35.5} alloy coating prepared in Example 2 of the present disclosure, wherein the radial intensity profile is corresponding to the SAED pattern.

FIGS. 8A to 8C show an SEM image of a cross-section (FIG. 8A), an SAED pattern (FIG. 8B), and a radial intensity profile (FIG. 8C) of the Cr_{15.0}Zr_{78.8}N_{6.2} alloy coating prepared in Example 3 of the present disclosure, wherein the radial intensity profile is corresponding to the SAED pattern.

FIG. 9 shows an SEM image of a cross-section of a Cr_{15.0}Zr_{49.5}N_{35.5} alloy coating prepared in Example 4 of the present disclosure.

FIGS. 10A to 10C show an XRD pattern (FIG. 10A), an SAED pattern (FIG. 10B), and a radial intensity profile (FIG. 10C) of the Cr_{15.0}Zr_{49.5}N_{35.5} alloy coating prepared in Example 4 of the present disclosure, wherein the radial intensity profile is corresponding to the SAED pattern.

FIG. 11 shows an SEM image of a cross-section of a Cr_{29.7}Zr_{50.1}N_{20.2} alloy coating prepared in Example 5 of the present disclosure.

FIG. 12 shows an XRD pattern of a Cr_{29.7}Zr_{50.1}N_{20.2} alloy coating prepared in Example 5 of the present disclosure.

FIG. 13 shows an SEM image of a cross-section of a Cr_{88.9}Zr_{11.1} alloy coating prepared in Comparative Example 1 of the present disclosure.

FIG. 14 shows an SEM image of a cross-section of a Cr_{37.8}Zr_{16.2}N₄₆ alloy coating prepared in Comparative Example 2 of the present disclosure.

FIGS. 15A to 15C show an XRD pattern (FIG. 15A), an SAED pattern (FIG. 15B), and a radial intensity profile (FIG. 15C) of a Cr_{37.8}Zr_{16.2}N₄₆ alloy coating prepared in Comparative Example 2 of the present disclosure, wherein the radial intensity profile is corresponding to the SAED pattern.

FIGS. 16A to 16C show an XRD pattern (FIG. 16A), an SAED pattern (FIG. 16B), and a radial intensity profile (FIG. 16C) of a Cr_{39.6}Zr_{19.4}N₄₁ alloy coating prepared in Comparative Example 4 of the present disclosure, wherein the radial intensity profile is corresponding to the SAED pattern.

### EXPLANATION OF REFERENCE SIGNS

1 represents vacuum chamber, 2 represents sample table, 3 represents electrical connection to direct current (DC) power supply, 4 represents chromium target (also denoted as Cr target), and 5 represents zirconium target (also denoted as Zr target);

100 represents substrate, 200 represents transition layer (also referred to as transition film layer), 300 represents Cr—Zr—N alloy coating, and 400 represents surface layer (also referred to as surface film layer).

In the present disclosure, unless otherwise specified, a chromium target 4 is a Cr target electrically connected to a radio frequency (RF) assisted DC power supply, and a zirconium target 5 is a Zr target electrically connected to a RF assisted DC power supply.

### DETAILED DESCRIPTION

The present disclosure is further described in detail below in conjunction with accompanying drawings, embodiments and examples. It should be understood that these embodiments and examples are only used to illustrate the present disclosure and are not intended to limit the scope of the present disclosure, and that these embodiments and examples are provided for the purpose of enabling a more thorough and comprehensive understanding of the content of the present disclosure. It should also be understood that the present disclosure can be realized in many different forms, and is not limited to the embodiments and examples described herein. The person skilled in the art can make various changes or modifications without departing from the concept of the present disclosure, and the equivalent forms obtained also fall within the protection scope of the present disclosure. For example, a feature stated or described as part of one embodiment can be combined in another embodiment in a suitable manner to obtain a new embodiment. Furthermore, in the description below, a great deal of details is given in order to provide a comprehensive understanding of the present disclosure, and it should be understood that the present disclosure can be implemented without one or more of these details.

Unless otherwise defined, all technical and scientific terms used herein have the same meaning as commonly understood by those of ordinary skill in the art to which the present disclosure pertains. The terms used in the specification of the present disclosure herein are for the purpose of describing specific embodiments only and are not intended to limit the present disclosure.

### Terms

Unless otherwise stated or there is a contradiction, terms or phrases used herein have the following meanings.

In the present disclosure, the terms “and/or”, “or/and”, “as well as/or”, when used in a list of two or more relevant listed items, mean that any one of the relevant listed items can be selected, and any and all combinations of the relevant listed items can be selected. The “any and all combinations” include combinations of any two or more of the relevant listed items, as well as a combination of all of the relevant listed items. For example, “A and/or B” includes three parallel solutions, i.e., A, B and a combination of A and B.

In the present disclosure, the terms “a plurality of”, “multiple”, “many times” and the like refer to a number equal to or greater than 2, unless otherwise specified. For example, “one or more” means one, two, or more.

In the present disclosure, unless otherwise specified, “one or more” means any one of the listed items or any combination of the listed items. Similarly, other expressions for “one or more”, such as “one or multiple”, should be understood in the same way unless otherwise specified.

In the present disclosure, the terms “a combination thereof”, “any combination thereof”, “any combination manner thereof”, and the like used herein include all suitable combinations of any two or more of the listed items.

In the present disclosure, “suitable” in the terms such as “suitable combination manner”, “suitable manner”, and “any suitable manner”, is defined based on the ability to implement the technical solutions as described in the present disclosure, to solve the technical problems as described in the present disclosure, and to realize the expected technical effects as described in the present disclosure.

In the present disclosure, the terms “preferably”, “better”, “preferred” and “appropriate” are only used to describe embodiments or examples with better effects, and it should be understood that they do not constitute a limitation on the protection scope of the present disclosure. If there are multiple “preferably” in a same technical solution, without otherwise specified and without a contradiction or mutual restriction, each “preferably” is considered independently from each other.

In the present disclosure, “further”, “furthermore”, “specially”, “for example”, “such as”, “exemplary”, “for instance”, etc., are used for descriptive purposes, indicating that the technical solutions before and after are related in terms of content, but the latter should not be understood as a limitation on the former technical solution, nor can be understood as a limitation on the protection scope of the present disclosure. Unless otherwise stated, A (such as B) means that B is a non-limiting example of A, and it should be understood that A is not limited to B.

In the present disclosure, “optionally”, “optional”, and “option” mean non-mandatory, indicating two parallel solutions with or without the optional feature. If there is more than one “option” in a same technical solution, unless otherwise specified or there is a contradiction or mutual restriction, each “option” is independent from the others. In the present disclosure, the descriptions such as “optionally contain” and “optionally include” mean “include or not include”. An “optional component X” means presence or absence of the component X.

In the present disclosure, the terms “first”, “second”, “third”, “fourth”, etc., in “first aspect”, “second aspect”, “third aspect”, “fourth aspect”, etc., are used for descriptive purposes only and are not to be construed as indicating or implying relative importance or quantity, or as implicitly specifying the importance or quantity of the technical features indicated. Moreover, “first”, “second”, “third”, “fourth” and the like only serve the purpose of non-exhaustive enumeration, and it should be understood that they do not constitute a closed-ended limitation on the quantity.

Unless otherwise specified, the terms “contain” “include” and “comprise” mentioned in the present disclosure are synonyms, which are inclusive or open-ended and are not intended to exclude additional or unmentioned members, elements, or method steps.

In the present disclosure, an open-ended description for the technical features encompasses not only a close-ended technical solution consisting of the listed features, but also an open-ended technical solution including the listed features.

In the present disclosure, when a numerical interval (i.e., a numerical range) is mentioned, unless otherwise specified, suitable values are considered as being continuously distributed within the numerical interval, and include two numerical endpoints (i.e., the minimum and maximum values) as well as every value between the two numerical endpoints. Unless otherwise specified, when the numerical interval refers to only integers in the numerical interval, the two end integers of the numerical interval and every integer between the two end integers are included, being equivalent to directly enumerating each integer. When multiple numerical ranges are provided to describe a feature or characteristic, these numerical ranges can be combined. In other words, unless otherwise indicated, the numerical ranges disclosed in the present disclosure should be understood to encompass any and all sub-ranges included therein. The “values” in the numerical interval can be any quantitative values, such as numbers, percentage, and ratios. The term “numerical interval” broadly encompasses types of numerical intervals, such as percentage intervals, proportion intervals, and ratio intervals.

In the present disclosure, unless otherwise limited, “about” means fluctuation within a certain range, fluctuating to above or below the modified number. The fluctuation range can vary depending on the type and numerical value of the modified number. For example, ±2%, ±1%, and =0.5% of the modified number are allowed, such as “about 2°” means the number can be selected from 2°±0.02°.

In the present disclosure, when a temperature parameter is mentioned, unless otherwise specifically stated, not only a thermostatic process but also a variation within a certain temperature interval is allowed. The thermostatic process allows for temperature fluctuations within the accuracy range of the instrument, such as fluctuations within the range of ±5 °C, +4 °C, ±3 °C, ±2 °C and ±1 °C. The temperature unit °C refers to “Celsius degree”.

In the present disclosure, the term “room temperature” generally refers to 4 °C to 35 °C, for example, 20 °C±5 °C. In some embodiments of the present disclosure, “room temperature” refers to 10 °C to 30 °C. In some embodiments of the present disclosure, “room temperature” refers to 20 °C to 30 °C.

In the present disclosure, the term “normal temperature” generally refers to 20 °C to 35 °C, for example, 20 °C to 35 °C. In some embodiments of the present disclosure, “normal temperature” refers to 30 °C to 35 °C. In some embodiments of the present disclosure, “normal temperature” refers to 30 °C.

In the present disclosure, for unit of a numerical range, if the unit only appears after the right endpoint, it means that the units of both the left endpoint and the right endpoint are the same. For example, “3 to 5 h” denotes that the unit hours (h) apply to both the left endpoint “3” and the right endpoint “5”, having the same meaning of “3 h to 5 h”. In addition, the above understanding is also applicable to similar descriptions relating to other parameters such as temperature, size, etc.

All documents referred to in the present disclosure are incorporated by reference in the present disclosure as if each document is individually incorporated by reference. Unless there is a conflict with the objects and/or the technical solutions of the present disclosure, the cited documents involved in the present disclosure are incorporated in their entireties and for all purposes. When the present disclosure cites documents, the definitions of relevant technical features, terms, norms, phrases, and the like in the cited documents are also cited. When the present disclosure cites documents, the examples and preferred modes of the related technical features that are cited can also be incorporated into the present disclosure by reference, provided that the present disclosure can be implemented. It should be understood that when the cited contents conflict with the description of the present disclosure, the present application should prevail or the cited contents shall be adaptively modified according to the description of the present disclosure.

The weights or masses of related components mentioned in the embodiments or examples of the present disclosure not only refer to specific contents of the components, but also represent proportional relationships between the weights or masses of the components. Therefore, enlargement or reduction in scale according the contents of the related components in the present application should be within the scope disclosed by the present application. Specifically, the units of the masses or weights described in the embodiments or examples of the present disclosure may be well known in the chemical industry, such as microgram (g), milligram (mg), gram (g), or kilogram (kg).

In the present disclosure, where multiple steps are involved in a method flow, unless specifically stated in the present disclosure, the order of the steps is not strictly limited, and these steps may be executed in other orders than that is described. In addition, any one of the steps described herein can include a plurality of sub-steps or stages. These sub-steps or stages are not necessarily executed at the same time, but may be executed at different times. The sub-steps or stages are not necessarily to be performed sequentially, but can be performed alternately or simultaneously with other steps or a part of the sub-steps or stages of other steps.

As to description of the positional relationships, unless otherwise specified, when an element such as a layer, a film, or a substrate is referred to as being “on” another layer or film, it may be directly on the other layer or film, or an intermediate layer or film may exist therebetween. Further, when a layer is referred to as being “under” another layer, it may be directly under the other layer, or one or more intermediate layers may exist therebetween. It may be also understood that when a layer is referred to as being “between” two layers, the layer may be the only layer between the two layers, or there may also exist one or more intermediate layers therebetween.

The terms “include”, “have”, and “contain” used in the present disclosure are indicates non-exclusive inclusion. Unless explicit limitation terms such as “only” and “consist of . . . ” are used, another component can also be further added.

Unless mentioned otherwise, a term in singular form can include plural form, and should not be construed as being only one in quantity.

In the present disclosure, exemplary descriptions such as “in some embodiments (or examples)”, “in an embodiment (or example)” and the like can include, but are not limited to, the following meanings: these solutions can be combined with other solutions in a suitable manner to form a new technical solution.

In order to improve the hardness of the coating, traditional alloy coatings mostly adopt nitrogen-rich alloy nitride coatings. Alloy nitride coatings are mainly composed of different metal elements to form coatings with different microstructures so as to achieve different functional characteristics. Traditional alloy coatings mostly adopt nitrogen-rich design to improve coating hardness, and the atomic percentage of nitrogen is usually higher than 40%. In addition, in order to improve the hardness, the traditional multi-element alloy coating also involves zirconium doping to improve the hardness to a certain extent. However, because zirconium is a large-size atom, its metal activity is higher than that of titanium, and its price is higher than that of titanium, so that titanium is commonly used instead of zirconium in alloy research and development. The content of zirconium in traditional alloys is usually not high, generally less than 10%.

Through numerous investigations, experiments, and analyses, the inventors of the present disclosure have found that the traditional hard coatings (such as TiN, etc.) tend to form columnar crystals therein during the nucleation and crystal growth process, usually exhibiting a columnar crystal structure. Moreover, a large amount of columnar crystals will promote the formation of a highly ordered structure with a directional arrangement. In the highly ordered structure, there are many inter-crystalline gap defects formed by the large amount of crystals, mainly manifesting as penetrating columnar gaps. Correspondingly, the scanning electron microscopic (SEM) image of the cross-section of the coating shows shadows between the columnar crystals, and it is speculated that these penetrating columnar gaps may lead to insufficient compactness of the alloy coating. The inventors of the present disclosure hypothesize that the conventional ordered structure with the directional arrangement may easily lead to insufficient coating compactness, thus limiting hardness improvement. On the other hand, under corrosive conditions, a corrosive medium can quickly penetrate the coating through the penetrating gaps and react with the substrate, resulting in unsatisfactory corrosion resistance of the alloy coating.

In addition, the alloy materials currently on the market mainly use methods such as anodizing, magnetron sputtering for surface protection. For example, aluminum alloys mainly use anodizing for surface protection. The working principle involves placing the aluminum alloy material into a strong acid or alkali solution to form an oxide and metal alloy coating on the surface, so as to form surface protection. Since the solution is strong acid or strong alkali, the hardness of the product formed by this method is relatively low. Furthermore, a large amount of waste water, waste liquid, and waste gas are produced in the production process, which is not conducive to environmental protection.

According to the present disclosure, a novel alloy nitride coating, which is a Cr—Zr—N alloy coating, with high zirconium content is formed by adopting a zirconium-rich alloy design and a careful selection of element composition and proportions. The alloy coating realizes novel alloy functions: The zirconium-rich Cr—Zr—N alloy coating provided by the present disclosure not only has high hardness, but also possesses excellent corrosion resistance much higher than that of the conventional hard coating, and thus is a hard coating with excellent corrosion resistance and high hardness.

According to various embodiments and examples of the present disclosure, a first aspect of the present disclosure provides a zirconium-rich Cr—Zr—N alloy coating including a Cr—Zr—N alloy material which is rich in zirconium. The Cr—Zr—N alloy coating not only has high hardness, but also has excellent corrosion resistance, and can be used as a protective coating of a coated article or a component thereof. Other aspects of the present disclosure also provide a coated article, use in the field of hard coating, and a preparation method.

In the zirconium-rich Cr—Zr—N alloy coating provided by the present disclosure, the Cr—Zr—N alloy material mainly includes three elements, chromium (Cr), zirconium (Zr), and nitrogen (N), and the three elements have a specific relative atomic ratio (CrₓZr_{y}N_{z}), where 15.0≤x≤53.8, 30.0≤y≤78.8, and 6.2≤z≤35.5. Based on the above-described zirconium-rich chemical composition, the Cr—Zr—N alloy coating has a highly disordered atomic distribution and a sufficiently densely packed atomic arrangement. The coating structure is dense, thus has a high hardness characteristic and excellent scratch resistance, which can reduce the occurrence of scratches or minimizing scratch damage. In addition, the special structure of the Cr—Zr—N alloy coating also reduces or eliminates the penetrating columnar gaps existed in conventional hard coatings, thus greatly improving the corrosion resistance of the Cr—Zr—N alloy coating. The Cr—Zr—N alloy coating provided by the present disclosure has high hardness and excellent corrosion resistance.

In a coated article, the Cr—Zr—N alloy coating provided by the present disclosure can be flexibly positioned. The Cr—Zr—N alloy coating can be in direct contact with the substrate or not in direct contact with the substrate, can be used as a surface layer, or can be positioned between the substrate and a surface layer of other structures as an intermediate film or layer. Regardless of its position, the Cr—Zr—N alloy coating of the present disclosure can effectively resist scratches and scrapes while providing excellent corrosion resistance. When used as the surface of the coated article, the Cr—Zr—N alloy coating provided by the present disclosure can form a high-brightness surface, serving both beautiful decorative and protective functions.

The Cr—Zr—N alloy coating provided by the present disclosure can be used as at least a part of a hard coating, and can be used as a surface film layer, an intermediate film layer, or a bottom film layer of the hard coating. The aforementioned coated article can be an intermediate product or a final product, and further can be used to prepare various products having the hard coating. The hard coating not only has a high hardness characteristic, but also can be used as a corrosion-resistant coating, providing excellent corrosion resistance.

The Cr—Zr—N alloy coating provided by the present disclosure can be applied to a variety of substrates, and the materials of the substrates include, but are not limited to, alloys, elemental metals, inorganic non-metal materials (such as silicon wafers, ceramics, and glass), etc.

The preparation method of the Cr—Zr—N alloy coating provided by the present disclosure is simple, easy to operate, green and environmentally friendly, has the advantages of being quantifiable, high efficiency, and good repeatability, and is suitable for industrial application.

The Cr—Zr—N alloy coating provided by the present disclosure can possess high hardness and excellent corrosion resistance even with a thin thickness, thereby saving raw materials, simplifying processes, shortening production cycles, and significantly reducing costs.

In a first aspect of the present disclosure, a zirconium-rich Cr—Zr—N alloy coating is provided, wherein the alloy material contained in the Cr—Zr—N alloy coating mainly includes three elements, Cr, Zr and N; Cr, Zr and N have a specific relative atomic ratio (CrₓZr_{y}N_{z}), where 15.0≤x≤53.8, 30.0≤y≤78.8, and 6.2≤z≤35.5. The zirconium-rich Cr—Zr—N alloy coating has a high content of zirconium, possessing high hardness and excellent corrosion resistance by optimizing the proportions of the three elements, and can be used as at least a part of a hard coating in a coated article.

In some embodiments, a zirconium-rich Cr—Zr—N alloy coating is provided, and the zirconium-rich Cr—Zr—N alloy coating includes a Cr—Zr—N alloy material, wherein the Cr—Zr—N alloy material is represented by a chemical formula of (CrₓZr_{y}N_{z})Mₐ, where x, y, z, and a are each independently an atomic proportion, 15.0≤x≤53.8, 30.0≤y≤78.8, 6.2≤z≤35.5, M is a doping element, and a is 0 or a positive number.

In some embodiments, a zirconium-rich Cr—Zr—N alloy coating is provided, and the zirconium-rich Cr—Zr—N alloy coating includes a Cr—Zr—N alloy material, wherein the Cr—Zr—N alloy material is represented by a chemical formula of (CrₓZr_{y}N_{z})Mₐ, where x, y, z, and a are each independently an atomic proportion, 15.0≤x≤53.8, 30.0≤y≤78.8, 6.2≤z≤35.5, Mis a doping element, and 0≤a/(x+y+z+a)≤0.05.

The Cr—Zr—N alloy coating provided in one aspect of the present disclosure can also be referred to as a “Cr—Zr—N alloy coating of the present application”, a “Cr—Zr—N alloy coating of the present disclosure”, an “exemplary Cr—Zr—N alloy coating of the present disclosure”, or a “Cr—Zr—N alloy coating provided in the present disclosure”, and includes, but is not limited to, the Cr—Zr—N alloy coating provided in the first aspect. Each of the above terms should be construed as non-limiting and not to be construed as limiting the scope of the present disclosure. For example, the scope of the present disclosure is not limited to the “Cr—Zr—N alloy coating of the present disclosure”. The descriptions such as the “Cr—Zr—N alloy coating of the present disclosure” and the like should be non-restrictively understood as an exemplary Cr—Zr—N alloy coating provided by one aspect of the present disclosure, and does not limit the scope of the Cr—Zr—N alloy coating provided by the present disclosure.

In the present disclosure, unless otherwise specified, “Cr—Zr—N alloy” and “CrZrN alloy” each refer to an alloy containing Cr, Zr, and N elements, and the alloy may also contain other alloying elements. The two terms can be used interchangeably.

In the present disclosure, unless otherwise specified, the “Cr—Zr—N alloy material” means an alloy material containing chromium (Cr), zirconium (Zr), and nitrogen (N) elements. In the Cr—Zr—N alloy material involved in the present disclosure, the three elements, Cr, Zr, and N, have the above-described specific atomic ratio x:y:z. In the present disclosure, the form of the Cr—Zr—N alloy material is not particularly limited, and can be, but is not limited to, a form of alloy coating layer.

In the present disclosure, unless otherwise specified, the “atomic ratio” of two or more elements refers to the ratio of the number of atoms.

In the present disclosure, unless otherwise specified, “Cr—Zr—N ternary alloy” and “CrZrN ternary alloy” each refer to an alloy composed of the three elements, i.e., Cr, Zr, and N elements.

In the zirconium-rich Cr—Zr—N alloy coating provided by the present disclosure, the Cr—Zr—N alloy material mainly includes three elements, Cr, Zr and N, and these three elements have a specific relative atomic ratio of CrxZryNz, where 15.0≤x≤53.8, 30.0≤y≤78.8, and 6.2≤z≤35.5. Based on the above-described zirconium-rich chemical composition, the Cr—Zr—N alloy coating has a highly disordered atomic distribution and a sufficiently densely packed atomic arrangement. The coating structure is dense, thus has a high hardness characteristic and excellent scratch resistance, which can reduce the occurrence of scratches or minimizing scratch damage. In addition, the special structure of the Cr—Zr—N alloy coating also reduces or eliminates the penetrating columnar gaps existed in conventional hard coatings, thus greatly improving the corrosion resistance of the Cr—Zr—N alloy coating. The Cr—Zr—N alloy coating provided by the present disclosure has high hardness and excellent corrosion resistance.

Since zirconium is a large-size atom with high atomic activity, it easily undergoes alloying and nitriding, and its nitrides or alloy nitrides exhibit relatively high hardness. In the present disclosure, by increasing the element content of zirconium in the alloy coating, on the one hand, the hardness of the alloy coating is effectively improved; and on the other hand, zirconium forms a specific atomic ratio with elements Cr and N in the Cr—Zr—N alloy material, such that a highly disordered atomic distribution and a sufficiently densely packed atomic arrangement can be formed during the deposition process in preparation of the coating, thereby further improving the hardness of the coating, reducing or avoiding penetrating columnar gaps, and significantly improving the corrosion resistance of the alloy coating.

The high hardness coating provides effects such as high hardness, low friction coefficient, and wear resistance, and when applied to substrates, such as metal substrates and alloy substrates, can achieve high hardness effect. As such, the coating with the characteristics of extremely high hardness and wear resistance is particularly suitable for structural parts that require high hardness and are prone to wear in fields such as 3C digital products, mechanical processing, mold manufacturing, geological drilling, textile industry, aerospace, and tool surfaces. For example, in the field of portable 3C products, such as the shell parts of mobile phones, which often rub against desktops, pockets, etc., requires high-hardness coating protection on the surface of the shell to increase the service life of the product. In another example, in the field of molds and tools, by adding a high-hardness alloy coating, the wear resistance of the molds or tools can be effectively increased, and the durability of the alloy tools can also be prolonged. In yet another example, in the aerospace field, the device shell forms overheating friction with air during extremely high-speed running, which easily leads to abrasion. By adding a high-hardness alloy coating on the surface of the shell, friction and abrasion can be reduced and the service life of the shell can be extended.

Corrosion-resistant coatings need to be self-inert and sufficiently isolated. “Self-inert” means that the material of the coating is enough inert to be less likely to chemically react with a corrosive medium in the operating environment. “Sufficiently isolated” means that the structure of the coating is sufficiently dense to adequately isolate the substrate from the application environment to prevent or delay the reaction between the substrate and the corrosive medium in the environment, thereby achieving the purpose of corrosion resistance.

Conventional hard coatings are usually in a nanocrystalline state and have a high content of columnar crystals. The coatings usually have numerous penetrating pores, which on the one hand reduces the compactness of the coating and thus affects the hardness characteristic, and on the other hand leads to poor corrosion resistance.

The Cr—Zr—N alloy coating provided by the present disclosure has a “highly disordered and sufficiently densely packed” characteristic structure, contains very few or no penetrating pores, and the coating structure is dense. Cr, Zr and N atoms with very different radii have a special atomic ratio, which is beneficial to make atoms condensed into a highly disordered state during deposition, and then sufficiently densely packed in the highly disordered state. The dual characteristics of “highly disordered distribution” and “sufficiently densely packed arrangement” of atoms in the coating make the alloy coating easy to grow densely, thereby improving the hardness of the coating, while inhibiting the formation of a large number of continuous penetrating gaps, thereby forming effective isolation between the substrate and the corrosive environment, significantly improving corrosion resistance. In addition, a relatively high Zr content is also beneficial to improve the chemical inertness of the coating in a corrosive environment. These factors synergistically and prominently improve the corrosion resistance of the Cr—Zr—N coating of the present disclosure.

In the Cr—Zr—N alloy coating of the present disclosure, based on the special atomic ratio of Cr, Zr, and N, Cr and N are introduced into a great amount of Zr to form a zirconium-rich Cr—Zr—N alloy coating, which can easily form strong bond energy between Cr and Zr, facilitating the rapid growth of Cr13 Zr alloy with an appropriate atomic ratio during the deposition process. In addition, the introduction of an appropriate amount of nitrogen further promotes re-nucleation of the Cr—Zr alloy, so as to form the Cr—Zr—N alloy of the present disclosure. By increasing the nucleation compactness of the coating, the hardness and corrosion resistance of the coating can be improved. In terms of atomic size, the atomic radius of Cr is 1.25 Angstroms (Å), the atomic radius of Zr is 1.60 Å, and the atomic radius of N is 0.71 Å. The atomic sizes of Cr and Zr are close, and the atomic size of N is smaller. During the nucleation process, an appropriate amount of small N atoms can infiltrate the pores between large Cr and Zr metal grains, where Cr and Zr have an appropriate atomic ratio, to achieve a desirable pore filling effect. As such, the atomic arrangement is denser, and the growth defects of the columnar crystal structure of the film can be suppressed, thereby improving the hardness and corrosion resistance of the coating.

In some embodiments, 64.5-y≤x≤93.8-y, and 15.0≤x≤1.93y-23.4. In this case, the three elements Cr, Zr, and N can generate a relatively good synergistic effect, which is conducive to improving the excellent comprehensive performance of the high hardness and the high corrosion resistance of the alloy coating.

In some embodiments, 15.0≤x≤53.8, 33.7≤y≤78.8, and 6.2≤z<28.0. Further, the following formulas can be satisfied: 72-y<x≤93.8-y, and 15.0≤x<2.5y-44.6. In this case, the atomic ratio of Cr, Zr, and N is favorable to the formation of the alloy coating with high compactness, high hardness, and high corrosion resistance.

In some embodiments, based on any suitable embodiments described above, the sum of x, y, and z is 100. In this case, x, y, and z correspond to the atomic percentages of the three elements of Cr, Zr, and N, respectively, and the ratio of the three elements of Cr, Zr and N is restricted within a more suitable range, which is beneficial for forming a Cr—Zr—N alloy coating with a more compact structure and realizing higher coating hardness and better corrosion resistance.

In some embodiments, when the proportional relationships of 15.0≤x≤53.8, 30.0≤y≤78.8, 6.2≤z≤35.5, and x+y+z=100 are satisfied, x can be any one of the following numerical values or selected from an interval between any two of the following numerical values: 15.0, 20.0, 25.0, 29.7, 30.0, 34.5, 35.0, 40.0, 41.3, 45.0, 47.1, 52.0, 53.8, etc..

In some embodiments, when the proportional relationships of 15.0≤x≤53.8, 30.0≤y≤78.8, 6.2≤z≤35.5, and x+y+z=100 are satisfied, y can be any one of the following numerical values or selected from an interval between any two of the following numerical values: 30.0, 33.2, 35.0, 35.1, 40.0, 45.0, 49.5, 50.0, 50.1, 55.0, 60.0, 65.0, 70.0, 75.0, 78.8, etc..

In some embodiments, when the proportional relationships of 15.0≤x≤53.8, 30.0≤y≤78.8, 6.2≤z≤35.5, and x+y+z=100 are satisfied, z can be any one of the following numerical values or selected from an interval between any two of the following numerical values: 6.2, 10.0, 10.1, 13.0, 15.0, 20.0, 20.2, 25.0, 25.5, 30.0, 35.5, etc..

In some embodiments, based on any suitable embodiments described above, the Cr—Zr—N alloy coating satisfies the following two features:
an X-ray diffraction (XRD) pattern of the Cr—Zr—N alloy material or the Cr—Zr—N alloy coating has one or more peaks in a diffraction angle 2 θ (°) range from 30° to 50°, and a full width at half maximum (FWHM) of at least one 2θ (°) diffraction peak in the range from 30° to 50° is greater than or equal to 2°; and
a radial intensity profile corresponding to a selected area electron diffraction (SAED) pattern of the Cr—Zr—N alloy material or the Cr—Zr—N alloy coating, with characteristic interatomic spacing as a horizontal axis and diffraction intensity as a vertical axis, has one or more diffraction peaks in a range from 2.0 Å to 3.0 Å, and a FWHM of at least one of the diffraction peaks in the range from 2.0 Å to 3.0 Å is greater than or equal to 0.21 Å

The means for characterizing the structure of the Cr—Zr—N alloy coating in the present disclosure can also be used to characterize the Cr—Zr—N alloy material of the present disclosure, and the Cr—Zr—N alloy material is not be limited to a coating, and can be an independent raw material, such as an alloy sheet, an alloy plate, or the like.

The Cr—Zr—N alloy coating provided by the present disclosure is not conventionally classified by perfect single crystal or sufficiently amorphous state, but focuses on a densely packing degree of atomic arrangement. On the basis of the specific atomic ratio of Cr, Zr, and N, the densely packing degree is closely related to the disorder degree of atomic arrangement and the appropriate mismatch degree of the atomic sizes. The Cr—Zr—N alloy coating with high compactness provided by the present disclosure achieves both high hardness and excellent corrosion resistance in performance, while in structure satisfying the features that its XRD pattern includes at least one wide peak (further, may not include sharp peaks, i.e., all peaks are wide peaks) in the diffraction angle 2θ (°) range from 30° to 50° and that its radial intensity profile of the SAED pattern includes at least one wide peak (further, may not include sharp peaks, i.e., all peaks are wide peaks) in the range from 2.0 Å to 3.0 Å.

In the present disclosure, whether the composition atoms of the alloy coating have a “highly disordered” state is evaluated by using XRD technology. More specifically, the XRD pattern of the Cr—Zr—N alloy coating shows wide and gentle bumps, and these “wide and gentle bumps” are referred to as “wide peaks” of the 2θ (°) diffraction peaks. The length of a domain composed by orderly arranged atoms can be obtained from the value of FWHM of the wide peak by using the Scherrer formula. The calculation method is as follows: D=Kλ/(β×cos θ), where D is the length of the domain composed by orderly arranged atoms (representing the grain size in crystalline materials), K is the Scherrer constant, λ is the X-ray wavelength, β is the FWHM of the diffraction peak (FWHM, referring to the width of the diffraction peak at half of its maximum amplitude), and θ is the diffraction angle. It can be seen that the FWHM is inversely proportional to the length D, and the shorter the length D, the higher the disorder degree of the atomic distribution. Therefore, the FWHMs of diffraction peaks in a specific range in the XRD pattern can be used to reflect the degree of disordered distribution of atoms: the wider the FWHM, the shorter the length of the domain composed by orderly arranged atoms, and the more disordered the overall atomic distribution. The aforementioned gently risen “wide peaks” can reflect a highly disordered distribution of atoms throughout the material.

Generally speaking, the higher the order degree of atomic arrangement, the stronger the crystallinity, the easier the formation of large-size crystal grains over long distances, and the narrower the diffraction peaks in the XRD pattern. The high crystallinity is often accompanied by sharp peaks. However, the three kinds of atoms Cr, Zr, and N in the alloy coating of the present disclosure exhibit an overall highly disordered arrangement in the Cr—Zr—N alloy coating, so that the XRD pattern of the Cr—Zr—N alloy coating shows wide and gentle bumps (wide peaks). Specifically, at least one peak is a “wide peak” in the diffraction angle 2θ (°) range from 30° to 50°.

In the present disclosure, unless otherwise specified, a “wide peak” in an XRD pattern can be defined as a peak having a FWHM of greater than or equal to 2°. The FWHM of the wide peak further can be greater than or equal to 2.2°, still further can be greater than or equal to 2.23°, still further can be greater than or equal to 2.25°, still further can be greater than or equal to 2.3°, still further can be greater than or equal to 3°, still further can be greater than or equal to 3.5°, still further can be greater than or equal to 3.92°, still further can be greater than or equal to 4°, and still further can be greater than or equal to 5°. The FWHM of any one “wide peak” in the XRD pattern can independently be any one of the following values, can be greater than or equal to any one of the following values, can be greater than or equal to any one of the following values and less than or equal to 10°, or can be selected from an interval defined by any two of the following values: 2°, 2.23°, 2.25°, 2.5°, 3°, 3.5°, 3.52°, 3.92°, 4°, 4.50°, 5°, 5.5°, 5.56°, 6°, 6.5°, 7°, 7.5°, 8.42°, 8.5°, 9°, 9.5°, etc., and as non-limiting examples, can be selected from any one of the following ranges: 2° to 10°, 2° to 9.5°, 2.2° to 9°, 2.2° to 8.5°, 2.20° to 8.45°, 2.23° to 8.42°, etc.

In the present disclosure, unless otherwise specified, a “sharp peak” in an XRD pattern refers to a diffraction peak having a FWHM of less than 2°.

More specifically, in the Cr—Zr—N alloy coating provided by the present disclosure, the XRD pattern has one or more peaks in the diffraction angle 2θ (°) range from 30° to 50°, and at least one of the one or more diffraction peaks in the XRD pattern is a wide peak. The special microstructure state in which at least one peak is a “wide peak” can be expressed by “having at least one 2θ (°) diffraction peak with a FWHM of greater than or equal to 2° in the range from 30° to 50°” or “a FWHM of least one 2θ (°) diffraction peak in the range from 30° to 50° is greater than or equal to 2°”. The following method can be adopted to determine whether or not “having at least one 2θ (°) diffraction peak with a FWHM of greater than or equal to 2° in the range from 30° to 50°” is satisfied: In the XRD pattern, if the FWHM value of the 2θ (°) diffraction peak is greater than or equal to 2°, it is identified as a “wide peak”, and if the FWHM value of the 2θ (°) diffraction peak is less than 2°, it is identified as a sharp peak. At any specified 2θ (°) position, there can be no peak, a wide peak, or a sharp peak. In the XRD pattern of the Cr—Zr—N alloy coating provided by the present disclosure, the characteristic diffraction peak has a relatively obvious characteristic of a wide peak.

In contrast, in the conventional Cr—Zr—N alloy coatings with high contents of columnar crystals, the diffraction peaks in the diffraction angle 2θ (°) range from 30° to 50° are often sharp peaks with the FWHM values of less than 2°, without any wide peaks.

In the present disclosure, XRD patterns of alloy coatings can be obtained by using standard instruments and methods in the art. For example, a Bruker D8 Advance XRD diffractometer from Germany can be used.

In some embodiments, the XRD pattern of the Cr—Zr—N alloy coating of the present disclosure has one or more peaks in the diffraction angle 2θ (°) range from 30° to 50°, and at least one 2θ (°) diffraction peak in the range from 30° to 50° is a wide peak, where the FWHM value of the wide peak can be referred to the examples described above and below. Taking the FWHM of the wide peak being greater than or equal to 2.23° as an example, at least one 2θ (°) diffraction peak in the range from 30° to 50° is greater than or equal to 2.23°.

In some embodiments, the XRD pattern of the Cr—Zr—N alloy coating of the present disclosure has one wide peak in the diffraction angle 2θ (°) range from 30° to 50°, and the FWHM value of the wide peak can be referred to the examples described above and below.

In some embodiments, the XRD pattern of the Cr—Zr—N alloy coating of the present disclosure has two or more wide peaks in the diffraction angle 2θ (°) range from 30° to 50°, and the FWHM values of these wide peaks can be independently referred to the examples described above and below.

In some embodiments, in the XRD pattern of the Cr—Zr—N alloy coating of the present disclosure, all of the 2θ (°) diffraction peaks in the diffraction angle 2θ (°) range from 30° to 50° are wide peaks, that is, there are no sharp peaks, and the FWHM values of these wide peaks can be independently referred to the examples described above and below.

In some embodiments, the XRD pattern of the Cr—Zr—N alloy coating of the present disclosure has peaks in the diffraction angle 2θ (°) range from 30° to 50°, and the FWHM values of the 2θ (°) diffraction peaks in the range from 30° to 50° each independently is greater than or equal to 2°, further each independently is greater than or equal to 2.2°, further each independently is greater than or equal to 2.23°, further each independently is greater than or equal to 2.25°, further each independently is greater than or equal to 2.3°, further each independently is greater than or equal to 3°, further each independently is greater than or equal to 3.5°, further each independently is greater than or equal to 4°, and further each independently is greater than or equal to 5°.

In some embodiments, the XRD pattern of the Cr—Zr—N alloy coating of the present disclosure has only one diffraction peak in the diffraction angle 2θ (°) range from 30° to 50°, and the diffraction peak is a wide peak.

In some embodiments, the XRD pattern of the Cr—Zr—N alloy coating is obtained by using Copper Kα radiation.

In the present disclosure, the XRD pattern of the alloy coating can be obtained by using the following instrument and method: a Bruker D8 Advance XRD diffractometer from Germany, operating in θ-2θ mode with Copper Ka radiation having a wavelength λ of 0.15406 nm. The X-ray tube is operated at 40 kV and 40 mA, with a scanning range from 20° to 80° and a step size of 0.01° for precise scanning.

The FWHM value can be obtain by using routine analytical methods in the art, including but not limited to analytical software provided by the instrument supplier. For example, the steps for obtaining the FWHM value can include: first correcting the diffraction peak, which can include smoothing, subtracting the background, removing the Kα2 lines, subtracting the instrument broadening, etc., and then fitting the diffraction peak with the Pseudo-Voigt function to obtain the FWHM value of the diffraction peak.

There is no special limitation on the analysis software herein, and non-restrictively, EDP2XRD software (version 1.0. 0, copyright by Hongwei Liu, The Australian Center for Microscopy and Microanalysis, The University of Sydney) can be used to process the raw data of the pattern by the following procedure: First, scale calibration is performed. Then, the center of the transmission spot of the diffraction ring is determined. After that, the raw data is converted into an XRD pattern (wherein the electron wavelength is 0.00251 nanometers (nm), and the X-ray wavelength is 0.154 nm). Subsequently, the background is subtracted linearly from the diffraction peak, and then the result is fitted by the Voigt function to obtain the FWHM value of the corresponding diffraction peak.

Regarding the characterization of the densely packing degrees of atoms in the alloy coatings, conventional XRD patterns cannot be used for effective characterization. This is because when detecting physical vapor deposition (PVD) films or coatings at atomic scale sizes (e.g., <3 nm in diameter), XRD methods often have insufficient resolution due to the large wavelength of X-rays (>0.1 nm), and thus are not suitable for PVD films or coatings with low order (e.g., crystal grains or amorphous bodies with a diameter <3 nm).

In the present disclosure, whether the composition atoms of a coating are “sufficiently densely packed” is assessed by using an SAED pattern. Electron waves are adopted because of their significantly small wavelengths (<0.01 nm), thus resulting in a relatively high resolution. More specifically, if the SAED pattern shows only continuous diffraction rings with uniform brightness, and the diffraction rings are relatively wide, it indicates that the atoms in the coating are sufficiently densely packed in a highly randomly mixed manner. For quantitative characterization, the SAED pattern can be converted into a characteristic interatomic spacing (d)-radial intensity profile with the characteristic interatomic spacing (d) as the horizontal axis and the diffraction intensity as the vertical axis. If the diffraction ring is relatively wide in SAED pattern, the FWHM of the radial intensity profile is correspondingly wide, reflecting a high densely packing degree of atoms in the alloy coating.

In the present disclosure, in terms of atomic size, the atomic radius of Cr is 1.25 Å, the atomic radius of Zr is 1.60 Å, and the atomic radius of N is 0.71 Å. The three atoms with different diameters have an appropriate atomic size mismatch, and can form a sufficiently densely packed structure when they are highly randomly mixed. During the growth process of a PVD film or an alloy coating, the atoms in Cr—Zr—N alloy coating are sufficiently densely packed, so that the alloy coating is easy to grow densely, which can suppress the formation and growth of the columnar crystals that would otherwise arise due to localized ordering. This makes it difficult to form a large number of continuous penetrating pores. Therefore, the FWHM of the radial intensity profile can be used as a characteristic parameter of a sufficiently densely packed structure of an alloy coating to reflect the densely packing degree of atoms in the alloy coating. The larger the value of the FWHM, the better the densely packing degree of atoms in the alloy coating. In short, in the present disclosure, using the FWHM of a radial intensity profile of an SAED pattern as the characteristic parameter of sufficient atomic densely packing conforms to scientific principles and is scientific.

When the FWHM of the radial intensity profile is greater than a certain threshold, the atoms achieve densely packing in the coating. According to extensive experimental exploration by the inventors, in the present disclosure, unless otherwise specified, the FWHM threshold in the SAED-radial intensity profile for determining whether densely packing of atoms has been achieved is set to 0.21 Å, i.e., densely packing of atoms is considered to be achieved when the FWHM value is greater than or equal to 0.21 Å.

In the present disclosure, the characteristic interatomic spacing (d) radial intensity profile of an alloy coating sample is obtained by using transmission electron microscopy (TEM) technology.

In the present disclosure, the radial intensity profile corresponding to the SAED pattern of the alloy coating can be referred to as an SAED-radial intensity profile, and can also be referred to as a characteristic interatomic spacing-intensity quantitative profile of the SAED pattern. The SAED pattern obtained by the TEM technology can be referred to as a SAED pattern or an SAED pattern. The SAED-radial intensity profile obtained by the TEM technology can also be referred to as an SAED-radial intensity profile.

In the present disclosure, the SAED patterns of alloy coatings (including the Cr—Zr—N alloy coating of the present disclosure) can be obtained by standard instruments and methods in the art, and corresponding radial intensity profiles can be obtained according to the SAED patterns. The radial intensity profiles are expressed in the form of characteristic interatomic spacing (d)-diffraction intensity, with interatomic spacing (d) in unit of Angstroms (Å) as the horizontal axis, and electron diffraction intensity (intensity) in unit of a.u. as the vertical axis.

In the present disclosure, unless otherwise specified, in the radial intensity profile of the SAED pattern, a diffraction peak is identified as a wide peak if the FWHM value thereof is greater than or equal to 0.21 Å, and a diffraction peak is identified as a sharp peak if the FWHM value thereof is less than 0.21 Å. At a specific characteristic interatomic spacing, there can be no peak, a sharp peak, or a wide peak. In the radial intensity profile of the Cr—Zr—N alloy coating provided by the present disclosure, the characteristic diffraction peak has a relatively obvious characteristic of a wide peak. Unless otherwise specified, in the radial intensity profile of the SAED pattern, the “wide peak” refers to the diffraction peak with a FWHM value greater than or equal to 0.21 Å, and the “sharp peak” refers to the diffraction peak with a FWHM value less than 0.21 Å.

In the present disclosure, radial intensity profiles or SAED-radial intensity profiles can be obtained by using the TEM technology, unless otherwise specified.

In the present disclosure, unless otherwise specified, a “wide peak” in the radial intensity profile corresponding to the SAED pattern can be defined as a peak having a FWHM of greater than or equal to 0.21 Å. The FWHM of the wide peak further can be greater than or equal to 0.25 Å, still further can be greater than or equal to 0.3 Å, still further can be greater than or equal to 0.4 Å, still further can be greater than or equal to 0.45 Å, still further can be greater than or equal to 0.5 Å.

In the present disclosure, the FWHM data in the radial intensity profile corresponding to the SAED pattern can be obtain by using (but not limited to) the following TEM method:

TEM test sample preparation: A sample is thinned by using Helios 5 CX focused ion beam (FIB) from ThemoFisher Co., Ltd., USA, to obtain an electronically transparent, TEM-observable planar sample.

SAED pattern acquisition: An SAED pattern of the sample is obtained by using a Talos F200x transmission electron microscope (TEM) from ThemoFisher Co., Ltd., USA, with an electron acceleration voltage of 200 kilovolts (kV) and a selected area aperture diameter of 900 nm. The radial intensity profile is obtained based on the SAED pattern, and the FWHM value of the diffraction peak is obtained by using an integration method.

According to the principle that the FWHM of the diffraction peak in the radial intensity profile corresponds to the width of the diffraction ring in the SAED pattern, the SAED pattern of the alloy coating can be converted into the corresponding radial intensity profile.

It should be understood by those skilled in the art that, the larger the width of the diffraction ring in the SAED pattern, the higher the degree of random mixing of atoms, and the more sufficient the densely packing of atoms in the Cr—Zr—N alloy coating of the present disclosure. The FWHM of the diffraction peak in the radial intensity profile is a quantitative index of the width of the diffraction ring, and the larger the FWHM value, the more sufficient the densely packing of atoms.

In some embodiments, the selective area electron diffraction (SAED) pattern of the Cr—Zr—N alloy coating of the present disclosure is obtained by using transmission electron microscope (TEM) characterization in a mode with an electron acceleration voltage of 200 kV and a selected area aperture of 900 nm.

In some embodiments, the radial intensity profile of the SAED pattern of the Cr—Zr—N alloy coating of the present disclosure has at least one diffraction peak having a FWHM greater than or equal to 0.21 Å in the range from 2.0 Å to 3.0 Å.

In the radial intensity profile of the Cr—Zr—N alloy coating provided by the present disclosure, the FWHM of the diffraction peak in the range from 2.0 Å to 3.0 Å has an upper limit due to the maximum densely packing of atoms, and a non-limiting example of this upper limit is, for example, 3.0 Å.

In the present disclosure, the FWHM of the “wide peak” in the radial intensity profile corresponding to the SAED pattern can be independently any one of the following values, can be greater than or equal to any one of the following values, can be greater than or equal to any one of the following values and less than or equal to the above upper limit (e.g., 3 Å), or can be independently selected from an interval defined by any two of the following values: 0.21 Å, 0.25 Å, 0.3 Å, 0.35 Å, 0.37 Å, 0.4 Å, 0.41 Å, 0.45 Å, 0.5 Å, 0.55 Å, 0.6 Å, 0.7 Å, 0.73 Å, 0.74 Å, 0.75 Å, 0.8 Å, 0.9 Å, 1.0 Å, 1.02 Å, 1.05 Å, 1.1 Å, 1.2 Å, 1.5 Å, 2.0 Å, 2.5 Å, etc. As non-limiting examples, the FWHM of the “wide peak” in the radial intensity profile corresponding to the SAED pattern can be selected from any one of the following ranges: 0.21 Å to 3.0 Å, 0.21 Å to 2.0 Å, 0.21 Å to 1.5 Å, 0.21 Å to 1.1 Å, 0.21 Å to 1.0 Å, 0.21 Å to 0.8 Å, 0.21 Å to 0.75 Å, 0.25 Å to 3.0 Å, 0.25 Å to 2.0 Å, 0.25 Å to 1.5 Å, 0.25 Å to 1.0 Å, 0.25 Å to 0.8 Å, 0.25 Å to 0.75 Å, 0.3 Å to 3.0 Å, 0.3 Å to 2.0 Å, 0.3 Å to 1.5 Å, 0.3 Å to 1.0 Å, 0.3 Å to 0.8 Å, 0.3 Å to 0.75 Å, 0.35 Å to 3.0 Å, 0.35 Å to 2.0 Å, 0.35 Å to 1.5 Å, 0.35 Å to 1.0 Å, 0.35 Å to 0.8 Å, 0.35 Å to 0.75 Å, 0.37 Å to 0.74 Å, etc.

In some embodiments, in the radial intensity profile of the Cr—Zr—N alloy coating, the FWHM value(s) of the diffraction peak(s) in the range from 2.0 Å to 3.0 Å is less than or equal to 3.0 Å.

In some embodiments, in the radial intensity profile of the Cr—Zr—N alloy coating of the present disclosure, the FWHM values of the diffraction peaks in the range from 2.0 Å to 3.0 Å can each independently be any one of the following values, can each independently be greater than or equal to any one of the following values, or can each independently be selected from an interval defined by any two of the following values: 0.21 Å, 0.25 Å, 0.3 Å, 0.35 Å, 0.37 Å, 0.4 Å, 0.41 Å, 0.45 Å, 0.5 Å, 0.55 Å, 0.6 Å, 0.7 Å, 0.73 Å, 0.74 Å, 0.75 Å, 0.8 Å, 0.9 Å, 1.0 Å, 1.02 Å, 1.05 Å, 1.1 Å, 1.2 Å, 1.5 Å, 2.0 Å, 2.5 Å, etc., and as non-limiting examples, can be selected from any one of the following ranges: 0.21 Å to 3.0 Å, 0.21 Å to 2.0 Å, 0.21 Å to 1.5 Å, 0.21 Å to 1.1 Å, 0.21 Å to 1.0 Å, 0.21 Å to 0.8 Å, 0.21 Å to 0.75 Å, 0.25 Å to 3.0 Å, 0.25 Å to 2.0 Å, 0.25 Å to 1.5 Å, 0.25 Å to 1.0 Å, 0.25 Å to 0.8 Å, 0.25 Å to 0.75 Å, 0.3 Å to 3.0 Å, 0.3 Å to 2.0 Å, 0.3 Å to 1.5 Å, 0.3 Å to 1.0 Å, 0.3 Å to 0.8 Å, 0.3 Å to 0.75 Å, 0.35 Å to 3.0 Å, 0.35 Å to 2.0 Å, 0.35 Å to 1.5 Å, 0.35 Å to 1.0 Å, 0.35 Å to 0.8 Å, 0.35 Å to 0.75 Å, 0.37 Å to 0.74 Å, etc.

In some embodiments, the radial intensity profile corresponding to the SAED pattern of the Cr—Zr—N alloy coating of the present disclosure has one wide peak in the range from 2.0 Å to 3.0 Å, and the FWHM value thereof can be referred to the examples described above and below.

In some embodiments, the radial intensity profile corresponding to the SAED pattern of the Cr—Zr—N alloy coating of the present disclosure has two or more wide peaks in the range from 2.0 Å to 3.0 Å, and the FWHM values thereof can be referred to the examples described above and below.

In some embodiments, in the radial intensity profile corresponding to the SAED pattern of the Cr—Zr—N alloy coating of the present disclosure, all diffraction peaks in the range from 2.0 Å to 3.0 Å are wide peaks, and the FWHM values of all diffraction peaks are greater than or equal to 0.21 Å, which can also be referred to the examples described above and below.

In some embodiments, the characteristic interatomic spacing of the Cr—Zr—N alloy coating of the present disclosure is obtained from TEM diffraction data, using an electron acceleration voltage of 200 kV and a selected area aperture diameter of 900 nm for TEM diffraction testing of the alloy coating.

In some embodiments, the SAED pattern of the Cr—Zr—N alloy coating is obtained by from TEM characterization in a mode with an electron acceleration voltage of 200 kV and a selected area aperture diameter of 900 nm.

Regarding the analysis of the intrinsic mechanism for the high hardness and excellent corrosion resistance of the Cr—Zr—N alloy coating of the present disclosure, the inventors of the present disclosure that has found through extensive experiments and researches that, for the Cr—Zr—N alloy coating, the prepared Cr—Zr—N alloy coating has high hardness and excellent corrosion resistance when the following two features are simultaneously satisfied: (1) the XRD diffraction pattern has at least one wide peak in the diffraction angle 2θ (°) range from 30° to 50°, and (2) the radial intensity profile of the SAED pattern has at least one wide peak in the range from 2.0 Å to 3.0 Å. If only the feature of the XRD diffraction pattern having at least one wide peak in the diffraction angle 2θ (°) range from 30° to 50° is satisfied, but no wide peak can be found in the radial intensity profile of the SAED pattern in the range from 2.0 Å to 3.0 Å, the Cr—Zr—N alloy coating may exhibit poor corrosion resistance; for example, the corresponding aluminum alloy substrate sample may fail to pass the 24-hour or 48-hour corrosion resistance evaluation by salt spray test. Conversely, if the radial intensity profile of the SAED pattern has at least one wide peak in the range from 2.0 Å to 3.0 Å, but the XRD diffraction pattern has no wide peak in the diffraction angle 2θ (°) range from 30° to 50°, the Cr—Zr—N alloy coating may also exhibit poor corrosion resistance.

In some embodiments, based on any suitable embodiments described above, the thickness of the Cr—Zr—N alloy coating is in a range from dₘᵢₙ to 6 μm, wherein dₘᵢₙ can be selected from 10 nm to 50 nm, dₘᵢₙ can also be any one of the following thicknesses, or can be selected from an interval defined by any two of the following thicknesses: 10 nm, 20 nm, 25 nm, 30 nm, 40 nm, 50 nm, etc.. For example, the thickness of the Cr—Zr—N alloy coating can be: 25 nm to 6 μm, 30 nm to 6 μm, 40 nm to 6 μm, 50 nm to 6 μm, 1.0 μm to 2.5 μm, 1.0 μm to 2.0 μm, etc. The dimension unit “μm” represents “micron”, and “nm” represents “nanometer”.

By controlling the Cr—Zr—N alloy coating of the present disclosure to have an appropriate thickness, the high hardness characteristic and/or corrosion resistibility of the alloy protective coating can be exerted more effectively. A thicker Cr—Zr—N alloy coating is more favorable to improving the hardness and/or corrosion resistance thereof. Whereas, the Cr—Zr—N alloy coating of the present disclosure can have both high hardness and high corrosion resistance even with a relatively thin thickness, thereby saving raw materials, simplifying processes, shortening production cycles, and significantly reducing costs. Compared with the conventional Zr-containing alloy coating, at the same thickness, the Cr—Zr—N alloy coating of the present disclosure can have a denser structure, resulting in higher hardness and better corrosion resistance.

In some embodiments, the thickness of the Cr—Zr—N alloy coating is in a range from 10 nm to 6 μm.

In some embodiments, the thickness of the Cr—Zr—N alloy coating is in a range from 25 nm to 6 μm.

In some embodiments, the thickness of the Cr—Zr—N alloy coating is in a range from 1 μm to 2.5 μm.

In addition, when the alloy coating is relatively thin, the formed coated article can show a silver-white metal color, which is close to the metal color of the substrate material, being conducive to achieving a beautiful decorative effect without changing the color of the substrate material.

The Cr—Zr—N alloy coatings provided by various embodiments of the present disclosure can be doped with or without other elements, which can be flexibly selected according to additional functional requirements of the alloy material and/or the alloy coating. It can be understood that in the present disclosure, when a doping element is included, the type and the doping amount of the doping element are not limited provided that the high hardness and high corrosion resistance of the Cr—Zr—N alloy coating can be achieved.

In the present disclosure, the chemical formula of the Cr—Zr—N alloy material contained in the Cr—Zr—N alloy coating can be represented by (CrₓZr_{y}N_{z})Mₐ, where x, y, and z are each independently an atomic proportion and are each a positive number, M is a doping element, and a is an atomic proportion of element M and is zero or a positive number. During the nucleation process, nitrogen atoms can infiltrate the pores between large Cr and Zr metal grains to achieve a relatively good pore filling effect, making the atoms in the coating layer sufficiently densely packed, and also suppressing the columnar crystal structure growth defects, thereby improving the corrosion resistibility of the coating layer.

When a is zero, the Cr—Zr—N alloy material does not include a doping element, corresponding to a Cr—Zr—N ternary alloy material. When a>0, the Cr—Zr—N alloy material includes a doping element, wherein a/(x+y+z) numerically equals the “relative atomic percentage of the doping element relative to Cr, Zr and N”, and a/(x+y+z+a) numerically equals the “atomic percentage of the doping element in the Cr—Zr—N alloy material”. The “relative atomic percentage of doping element M relative to Cr, Zr, and N” refers to the ratio of the number of atoms of doping element M to the total number of Cr, Zr, and N atoms in the material, and is expressed in the form of a percentage.

Unless otherwise specified, the Cr—Zr—N alloy material according to various embodiments of the present disclosure mainly includes three elements, Cr, Zr, and N; further, the ratio of the combined atomic proportion of the three elements in the total atomic proportion of all elements in the Cr—Zr—N alloy material is greater than or equal to 95% (corresponding to 0≤a/(x+y+z+a)<0.05, further such as 0≤a/(x+y+z)≤0.05), further such as greater than or equal to 98% (corresponding to 0≤a/(x+y+z)≤0.02, further such as 0≤a/(x+y+z)≤0.02), and a further example can be a Cr—Zr—N ternary alloy material (where a=0). By limiting the concentration of the doping element, the influence of the doping element on the highly disordered and sufficiently densely packed arrangement of atoms in the Cr—Zr—N alloy coating of the present disclosure can be reduced as much as possible, which is beneficial to the reduction of the concentration of the element required for doping or the difficulty of doping, thereby simplifying the preparation process, and promoting the synergistic deposition of Cr, Zr and N to form a relatively dense coating. This approach supports achieving relatively high hardness and relatively good corrosion resistance.

In some embodiments, a/(x+y+z)=0, which corresponds to a Cr—Zr—N ternary alloy material. This composition is simple, and is casier to be prepared and controlled. The resulting Cr—Zr—N ternary alloy coating can have a dense structure, and can achieve high hardness and high corrosion resistance.

In some embodiments, 0<a/(x+y+z+a)≤0.05. a/(x+y+z+a) can be any one of the following values, or can be less than or equal to any one of the following values but greater than 0, or can be selected from a numerical range defined by any two of the following values: 0.0001, 0.0005, 0.001, 0.005, 0.01, 0.015, 0.02, 0.03, 0.04, 0.05, etc.

In some embodiments, 0<a/(x+y+z)≤0.05. a/(x+y+z) can be any one of the following values, or can be less than or equal to any one of the following values but greater than 0, or can be selected from a numerical range defined by any two of the following values: 0.0001, 0.0005, 0.001, 0.005, 0.01, 0.015, 0.02, 0.03, 0.04, 0.05, etc.

In some embodiments, 0<a/(x+y+z+a)≤0.02, further for example, 0<a/(x+y+z+a)≤0.02, 0≤a/(x+y+z+a)≤0.01, 0<a/(x+y+z+a)≤0.01, 0<a/(x+y+zta)<0.01 etc. In some embodiments, 0≤a/(x+y+z)≤0.02, further for example, 0<a/(x+y+z)≤0.02, 0≤a/(x+y+z)≤0.01, 0<a/(x+y+z)≤0.01, 0<a/(x+y+z)<0.01, etc. In these cases, the concentration of the doping element can be controlled at a relatively low level, which can minimize the influence of the doping element on the highly disordered and sufficiently densely packed arrangement of atoms in the Cr—Zr—N alloy coating, which is beneficial to the reduction of the concentration the element required for doping or the difficulty of doping, thereby simplifying the preparation process, and promoting the synergistic deposition of Cr, Zr and N to form a relatively dense coating. This approach supports achieving relatively high hardness and relatively good corrosion resistance.

In some embodiments, the doping element is a non-metal element, a metal element, or a combination thereof, which can be flexibly selected according to the additional functional requirements of the Cr—Zr—N alloy coating. It can be understood that in the present disclosure, when the doping element is included, the type and the doping amount of the doping element are limited such that the Cr—Zr—N alloy coating structure of the present disclosure can be formed without negatively affecting the realization of high hardness and corrosion resistance.

Non-restrictively, the non-metal element can include O, C, B, Si, Ar, or any combination thereof. Non-restrictively, the metal element can include Ti, V, Nb, Mo, Hf, Ta, W, Ni, Mo, Fe, Ag, Au, Cu, Al, or any combination thereof.

It should be noted that, in any one of the embodiments of the present disclosure, inevitable impurities introduced during the preparation process are allowed to exist in the Cr—Zr—N alloy coating and the related Cr—Zr—N alloy material provided by the present disclosure. The “inevitable impurities” are not intentionally added impurities, and the main reason for their existence is that they are introduced accidentally during the preparation process. Non-limiting examples of the “inevitable impurities”, can be such as C, O, etc. present in air, or from components in the raw materials or equipment. The atomic concentrations of the “inevitable impurities” in the Cr—Zr—N alloy coating is typically trace or micro, generally negligible, such as less than 0.01%. Taking the technical solution that “the Cr—Zr—N alloy coating is a Cr—Zr—N ternary alloy material composed of Cr, Zr, and N elements” as an example, theoretically, the Cr—Zr—N alloy coating consists of Cr, Zr, and N elements, but trace amounts or micro amounts of other elements other than Cr, Zr, and N elements, such as C and O, may be introduced during the preparation process.

In an aspect of the present disclosure, a Cr—Zr—N alloy material as defined in the first aspect of the present disclosure is further provided.

In a second aspect of the present disclosure, a coated article is provided, and the coated article includes a substrate 100 and the Cr—Zr—N alloy coating described in the first aspect of the present disclosure (such as the Cr—Zr—N alloy coating 300 shown in FIG. 1). The Cr—Zr—N alloy coating is located on at least one side of the substrate. The Cr—Zr—N alloy coating can be part of a protective coating of the coated article, endowing the protective coating with high hardness and excellent corrosion resistance.

The Cr—Zr—N alloy coating provided by the present disclosure can be located on one side or on both sides of the substrate.

In some embodiments, a surface material of the substrate an alloy, an elemental metal, or an inorganic non-metal material. Non-restrictively, a material type of the alloy can include nickel base, iron base, tungsten base, titanium base, silicon base, aluminum base, copper base, cobalt base, zirconium base, zinc base, or any combination thereof. Non-restrictively, the elemental metal can be zinc, gold, platinum, zirconium, hafnium, niobium, tantalum, nickel, copper, aluminum, iron, silver, or chromium. Non-restrictively, the inorganic non-metal material can include ceramic, glass, or a combination thereof. Non-restrictively, the inorganic non-metal material can include a silicon wafer.

Further, the Cr—Zr—N alloy coating provided by the present disclosure can be applied to a variety of substrates. The materials of the substrates include, but are not limited to, alloys, elemental metals, etc. The Cr—Zr—N alloy coating can also be applied to other types of substrates made of inorganic non-metal materials, such as silicon wafers, ceramics, and glass.

In some embodiments, the surface material of the substrate is a light alloy or a stainless-steel. Optionally, the light alloy can include a titanium alloy, an aluminum alloy, a magnesium alloy, or any combination thereof.

In some embodiments, the surface material of the substrate is a light alloy. Further, the light alloy can include a titanium alloy, an aluminum alloy, a magnesium alloy, or any combination thereof.

In some embodiments, the surface material of the substrate is a stainless-steel. Further, the stainless-steel can be austenitic stainless steel, ferritic stainless steel, martensitic stainless steel, etc.

In some embodiments, the coated article satisfies one or more of the following features:
the Cr—Zr—N alloy coating is in direct contact with the substrate (in this case, there is no transition layer), or a transition layer is disposed between the Cr—Zr—N alloy coating and the substrate; further, the transition layer can be a single-layer structure or a multi-layer structure (i.e., one or more structural layers can be formed between the Cr—Zr—N alloy coating of the present disclosure and the substrate);
the Cr—Zr—N alloy coating forms a surface of the coated article, or a surface layer is further disposed on a side of the Cr—Zr—N alloy coating away from the substrate; further the surface layer is a single-layer structure or a multi-layer structure (i.e., one or more structural layers can be further formed on the Cr—Zr—N alloy coating of the present disclosure).

In the present disclosure, unless otherwise specified, “transition layer” and “transition film layer” have the same meaning and can be used interchangeably, both referring to a structural layer with transitional properties located between the substrate and the Cr—Zr—N alloy coating in the coated article. This layer can be a single-layer structure or a multi-layer structure.

In the present disclosure, unless otherwise specified, “surface layer” and “surface film layer” have the same meaning, and can be used interchangeably, both referring to a structural layer located on the side of the Cr—Zr—N alloy coating away from the substrate and forming a surface of the coated article. This layer can be a single-layer structure or a multi-layer structure.

In some embodiments, the Cr—Zr—N alloy coating 300 is in direct contact with the substrate 100 (without a transition layer in this case).

In some embodiments, a transition layer 200 is disposed between the Cr—Zr—N alloy coating 300 and the substrate 100.

In some embodiments, the Cr—Zr—N alloy coating 300 forms a surface of the coated article.

In some embodiments, a surface layer 400 is further disposed on a side of the Cr—Zr—N alloy coating 300 away from the substrate 100.

FIG. 1 is a schematic structural view of a coated article including an exemplary Cr—Zr—N alloy coating according to an embodiment of the present disclosure, including a substrate 100 and a Cr—Zr—N alloy coating 300.

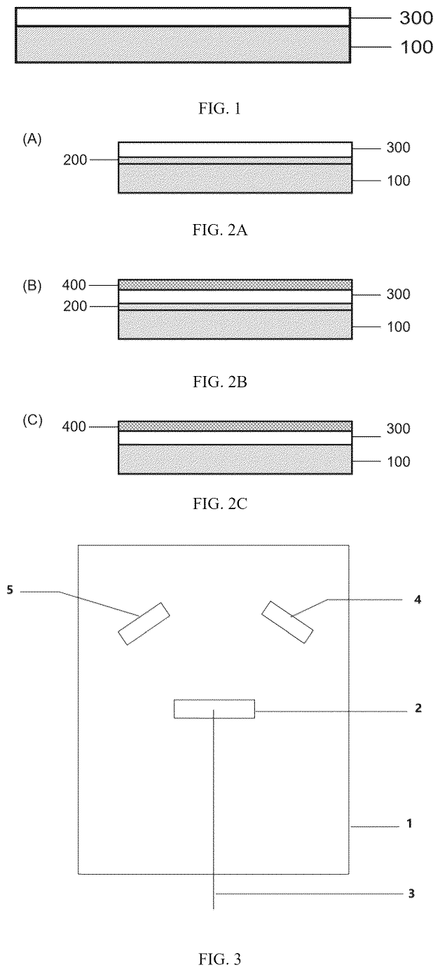

FIG. 2 is a schematic structural view of several coated articles according to several embodiments of the present disclosure: (A) including a substrate 100, a transition layer 200, and a Cr—Zr—N alloy coating 300; (B) including a substrate 100, a transition layer 200, a Cr—Zr—N alloy coating 300, and a surface layer 400; (C) including a substrate 100, a Cr—Zr—N alloy coating 300, and a surface layer 400.

In the coated article, the position of the Cr—Zr—N alloy coating provided by the present disclosure can be flexibly set. The Cr—Zr—N alloy coating can be in direct contact with the substrate or not in direct contact with the substrate, can be used as a surface layer, or can be an intermediate film layer positioned between the substrate and a surface layer of another structure. Regardless of its position, the Cr—Zr—N alloy coating of the present disclosure can effectively resist scratches and scrapes while providing excellent corrosion resistance.

When the Cr—Zr—N alloy coating of the present disclosure forms a surface of the coated article (in this case, the Cr—Zr—N alloy coating of the present disclosure is used as the surface layer of the coated article), the highly dense structure of the alloy coating also provides a relatively good reflection characteristic for the coating, thereby providing a bright surface for the coated article, enabling the coating to have both decorative and protective functions. To test the chromaticity of the alloy coating, samples are prepared with substrate materials suitable for practical application, allowing the evaluation of the improvement degree of the alloy coating on the compactness and other properties of the substrate. A CM-3700A-U desktop spectrophotometer manufactured by Konica, Japan can be used to test the values of L, a, and b of the samples. A F2 light source is selected for the light receiving system, and the average of six matrix points is taken for each sample. L represents brightness, a represents red or green chromaticity, and b represents yellow or blue chromaticity. The greater the value of L, the higher the brightness, and the denser the coating surface. The mechanism is as follows: The spectrophotometer can create a reflectivity curve of light reflected from the surface of the test sample. The amplitude of this curve reflects the density of the material, which can be characterized by L. For the same material, the higher the compactness, the greater the value of L.

Based on the difference of the main component of the substrate, the coated article can be any one selected from the group consisting of light alloy products, stainless-steel products, elemental metal products, inorganic non-metal-based products (such as ceramic-based products, silicon-based products, glass-based products), etc., indicating that the main component of the substrate can be light alloy, stainless steel, elemental metal, etc., respectively. Non-restrictively, the light alloy products can include, but are not limited to, aluminum alloy products, titanium alloy products, magnesium alloy products, and the like. Non-restrictively, the stainless-steel products can include, but are not limited to, austenitic stainless steel products, ferritic stainless steel products, martensitic stainless steel products. Non-restrictively, the elemental metal products can include, but are not limited to, products made of zinc, gold, platinum, zirconium, hafnium, niobium, tantalum, nickel, copper, aluminum, iron, silver, or chromium., and further such as copper, aluminum, iron, silver, or chromium.

In a third aspect of the present disclosure, use of the Cr—Zr—N alloy coating described in the first aspect of the present disclosure is provided.

The application fields of the Cr—Zr—N alloy coating described in the first aspect of the present disclosure include, but are not limited to, the conventional application fields of hard coatings, such as, but not limited to, 3C digital products, automotive parts or accessories, mechanical processing, mold manufacturing, geological drilling, textile industry, aerospace, and other products or technical fields.

Examples of the hard coatings in the third aspect of the present disclosure and application fields thereof can also be referred to the first aspect described above.

In some embodiments, use of the Cr—Zr—N alloy coating described in the first aspect of the present disclosure as at least a part of a hard coating is provided, or use of the coated article described in the second aspect of the present disclosure in the preparation of a product having a hard coating is provided. Further, the hard coating is also a corrosion-resistant coating. As a non-limiting example, the product having the hard coating can be a structural part that requires high hardness and is prone to wear in the fields such as 3C digital products, mechanical processing, mold manufacturing, geological drilling, textile industry, aerospace, tool surfaces, etc.

The Cr—Zr—N alloy coating provided by the present disclosure can be used as at least a part of the hard coating, can be used as a protective coating with a single structural layer, or can be used as one layer of a multi-layer structural protective coating, and can be used as a surface film layer, an intermediate film layer, or a bottom film layer of the hard coating. The coated article can be an intermediate product or a final product, and further can be used to prepare various products having a hard coating. The hard coating not only has a high hardness characteristic, but is also a corrosion-resistant coating providing excellent corrosion resistance

Further, the final product can be directly used or sold. The intermediate product can be further processed or assembled with other components into a new product.

In some embodiments, taking an aluminum alloy substrate as an example, a hard coating including the Cr—Zr—N alloy coating of the present disclosure formed on the surface of the aluminum alloy substrate can provide protection for at least 24 hours in a corrosion resistance evaluation by salt spray test, meaning that it can pass the 24-hour test, and in most embodiments, can also pass the 48-hour test. The ASTM B117 salt spray test method can be used, and or further reference can be made to the example section below. Under the same test conditions, conventional hard coatings generally fail to provide protection for more than 8 hours in the corrosion resistance evaluation by salt spray test.

The Cr—Zr—N alloy coating of the present disclosure used for protection can also provide better hardness and corrosion resistance compared to the conventional protective layer of the same thickness, and thus can have high hardness and excellent corrosion resistance even with a relatively thin thickness, thereby saving raw materials, simplifying processes, shortening production cycles, and significantly reducing costs.

In a fourth aspect of the present disclosure, a method for preparing a Cr—Zr—N alloy coating is provided, and the method includes a step of depositing composition elements of the Cr—Zr—N alloy coating on at least a portion of a surface of a substrate according to a preset atomic ratio of the composition elements by vapor deposition, thereby forming the Cr—Zr—N alloy coating as described in the first aspect of the present disclosure.

The method for preparing the Cr—Zr—N alloy coating provided by the present disclosure is simple, easy to operate, green and environmentally friendly, has the advantages of being quantifiable, high efficiency, and good repeatability, and is suitable for industrial application.

The definition of the substrate can refer to the second aspect of the present disclosure.

In some embodiments, the vapor deposition is physical vapor deposition. Further, the physical vapor deposition can be implemented by vacuum evaporation, sputtering, arc plasma plating, ion plating, molecular beam epitaxy, or any combination thereof.

In an embodiment, the physical vapor deposition is magnetron sputtering.

In some embodiments, the composition elements of the Cr—Zr—N alloy coating according to a predetermined atomic ratio are deposited on at least a portion of a surface of the substrate by sputtering (e.g., magnetron sputtering).

Referring to FIG. 3 showing a device, the device shown in FIG. 3 includes a vacuum chamber 1, a sample table 2, an electrical connection to a DC power supply 3, a chromium target 4, and a zirconium target 5. The chromium target 4 is a Cr target electrically connected to a RF assisted DC power supply, and the zirconium target 5 is a Zr target electrically connected to a RF assisted DC power supply. The figure is not drawn to a 1:1 scale, and the relative dimensions of the elements are drawn exemplarily in the figure only to facilitate understanding of the present disclosure, but are not necessarily drawn to true scale. The scale in the figure is not construed as limiting the present disclosure. A reactive sputtering process can occur with a gas containing N₂ (such as an Ar/N₂ mixed gas) within the vacuum chamber 1, forming the Cr—Zr—N alloy coating of the present disclosure.

In some embodiments, the method for preparing the Cr—Zr—N alloy coating includes the following step: under a condition of introducing a mixed gas containing argon gas and a nitrogen-containing gas, sputtering a target including chromium, zirconium, or a combination thereof to deposit the composition elements of the Cr—Zr—N alloy coating on at least a portion of a surface of a substrate, thereby forming the Cr—Zr—N alloy coating. The nitrogen-containing gas can be, but is not limited to, nitrogen gas. A flow rate ratio of argon gas to nitrogen gas in the mixed gas can be in a range from 2:1 to 6:1, for example, 2:1, 3:1, 4:1, 5:1, 6:1, etc. Selecting nitrogen gas as the nitrogen-containing gas and controlling the content of nitrogen gas can further adjust the performance of the Cr—Zr—N alloy coating of the present disclosure.

The target can include a chromium target, a zirconium target, an alloy target, or any combination thereof. The alloy target includes at least two metal elements in the Cr—Zr—N alloy coating. The atomic ratio of the metal elements in the alloy target can be the same or similar to the atomic ratio of the corresponding metal elements in the Cr—Zr—N alloy coating. In some embodiments, the alloy target is a chromium-zirconium-based alloy target, which includes at least chromium and zirconium, for example, a CrZr alloy target, a CrZrN alloy target, etc. In some embodiments, the atomic ratio of Cr to Zr in the chromium-zirconium-based alloy target, such as the CrZr alloy target, is 65%:35%. In some embodiments, the atomic ratio of Cr to Zr in the chromium-zirconium-based alloy target, such as the CrZr alloy target, is 55%:45%. In some embodiments, the alloy target includes all of the metal elements in the Cr—Zr—N alloy coating. Examples of alloy targets can be found in Examples 2 and 11 below.

In the present disclosure, unless otherwise specified, the “chromium-zirconium-based alloy target” includes at least chromium and zirconium, and can include or not include other elements. When other elements are included, it can be understood that the chemical composition of the target should generally be within the range of the predetermined chemical formula (CrₓZr_{y}N_{z})Mₐ. For example, the chromium-zirconium-based alloy target can be a chromium-zirconium-nitrogen alloy target consist of three elements: chromium, zirconium, and nitrogen (i.e., a CrZrN alloy target).

In some embodiments, a chromium zirconium alloy target can replace the chromium target 4 in FIG. 3, and be installed at the position where the original chromium target 4 is located in FIG. 3.

In some embodiments, a method for preparing a Cr—Zr—N alloy coating, for example, by using sputtering (such as magnetron sputtering), includes a step of under a condition of introducing a mixed gas containing argon gas and a nitrogen-containing gas, sputtering a chromium target and a zirconium target, or sputtering a chromium zirconium alloy target (i.e., the CrZr alloy target), to deposit the composition elements of the Cr—Zr—N alloy coating on at least a portion of a surface of a substrate, thereby forming the Cr—Zr—N alloy coating.

In some embodiments, before “sputtering to deposit the composition elements of the Cr—Zr—N alloy coating on at least a portion of a surface of a substrate”, the method further includes a step of cleaning the substrate. The method of cleaning the substrate can be a conventional cleaning method in the field, including but not limited to the field of decorative plating.

In some embodiments, cleaning the substrate includes the steps of: putting the substrate into water, ultrasonically cleaning the substrate in water for 10 minutes (min) to 15 min, vacuum drying the cleaned substrate for 15 min to 20 min, and placing the dried substrate on the sample table in a sputtering (such as magnetron sputtering) device. The sample table can be a rotatable sample table.

In an embodiment, the cleaning the substrate includes the steps of: putting the substrate into deionized water (DI water), and ultrasonically cleaning the substrate in the deionized water for 10 min to 15 min, placing the cleaned substrate into a vacuum oven and baking the cleaned substrate therein for 15 min to 20 min, and placing the dried substrate on a rotatable sample table in the vacuum chamber.

In some embodiments, the method further includes a step of forming a transition layer on at least a portion of a surface of the cleaned substrate after the step of “cleaning the substrate” and before the step of “sputtering to deposit the composition elements of the Cr—Zr—N alloy coating on at least a portion of a surface of a substrate”. For example, the composition elements of the transition layer can be deposited onto at least a portion of a surface of the cleaned substrate.

In some embodiments, a surface layer can be further deposited after forming the Cr—Zr—N alloy coating of the present application on one side of the substrate, and the surface layer can be a single-layer structure or a multi-layer structure.

In some embodiments, the temperature of the sputtering deposition is in a range from 30 °C to 330 °C, such as 30 °C, 40 °C, 50 °C, 60 °C, 70 °C, 80 °C, 90 °C, 100 °C, 150 °C, 200 °C, 250 °C, 300 °C, 330 °C, etc.

In some embodiments, the total gas-pressure of the mixed gas containing argon gas and the nitrogen-containing gas is in a range from 0.3 Pa to 1.2 Pa, for example, 0.3 Pa, 0.5 Pa, 0.8 Pa, 1 Pa, 1.2 Pa, etc., and the pressure unit Pa refers to “Pascal”.

In some embodiments, sputtering is performed by radio-frequency assisted direct current sputtering, which can further improve the efficiency of the sputtering deposition of the alloy coating compared with other preparation methods.

In some embodiments, the target includes a chromium target, and a power density for the chromium target is in a range from 1.3 W/cm² to 6.7 W/cm². The unit W/cm² refers to “watts per square centimeter”.

In some embodiments, the target includes a zirconium target, and a power density for the zirconium target is in a range from 0.8 W/cm² to 7.9 W/cm².

In some embodiments, the target includes a chromium target and a zirconium target, the power density for the chromium target is in a range from 1.3 W/cm² to 6.7 W/cm², and the power density for the zirconium target is in a range from 0.8 W/cm² to 7.9 W/cm².

In some embodiments, the target includes a chromium-zirconium-based alloy target, and the power density for the chromium-zirconium-based alloy target is in a range from 4 W/cm² to 6 W/cm².

In some embodiments, a bias voltage applied to the substrate is in a range from −150 V to −20 V, for example, −150 V, −120 V, −100 V, −90 V, −80 V, −60 V, −50 V, −40 V, −30 V, −20 V, etc., and the unit V refers to “volts”.

In some embodiments, a flow rate of the nitrogen-containing gas can be in a range from 8 sccm to 52 sccm, for example, 8 sccm, 10 sccm, 20 sccm, 25 sccm, 30 sccm, 40 sccm, 50 sccm, 52 sccm, etc. Further, the nitrogen-containing gas is nitrogen gas. The unit sccm (standard cubic centimeter per minute) is a unit of flow rate, and is used to characterize the gas flow rate.

In some embodiments, the time period of the sputtering deposition is in a range from 10 min to 150 min, such as 10 min, 15 min, 30 min, 45 min, 60 min, 90 min, 100 min, 120 min, etc. The thickness of the Cr—Zr—N alloy coating of the present application can be adjusted by adjusting the deposition time period. The thickness of the Cr—Zr—N alloy coating increases with the increase of the deposition time period.

In some embodiments, a background vacuum degree of the vacuum chamber used herein is less than or equal to 5.0×10⁻⁴ Pa. The pressure can ensure the collision between the sputtered particles and the gas molecules, while simultaneously reducing impurities entering into the gas molecules in the deposition process, so as to improve the corrosion resistance, purity, and binding force of the Cr—Zr—N alloy coating of the present application.

It can be understood that argon gas and the nitrogen-containing gas can be introduced into the vacuum chamber through a single passage, or previously mixed in a mixing cylinder and then introduced into the vacuum chamber, thereby reducing the impurity content of the Cr—Zr—N alloy coating of the present application and improving its performance.

In some embodiments, “loading the composition elements of the Cr—Zr—N alloy coating according to a predetermined atomic ratio on at least a portion of a surface of a substrate by using sputtering (e.g., magnetron sputtering)” includes the steps of: introducing a mixed gas including argon gas and a nitrogen-containing gas into the vacuum chamber 1, maintaining the pressure in the vacuum chamber 1 at 0.3 Pa to 1.2 Pa (e.g., 0.5 Pa to 0.8 Pa), applying a bias voltage of −150 V to −20 V, setting the power density for the chromium target 4 at 1.3 W/cm² to 6.7 W/cm², setting a power density for the zirconium target 5 at 0.8 W/cm² to 7.9 W/cm², and depositing the Cr—Zr—N alloy coating on at least a portion of a surface of a cleaned substrate. Further, Cr—Zr—N alloy coatings with different thicknesses can be prepared by controlling the deposition time.

In a fifth aspect of the present disclosure, a Cr—Zr—N alloy material is provided, which may be as defined in the first aspect of the present application, or may be a Cr—Zr—N alloy material in any one of the above-described embodiments herein. As mentioned above, the Cr—Zr—N alloy material has a suitable atomic size mismatch and a special atomic ratio, which allows the Cr—Zr—N alloy coating of the present disclosure to be formed with a relatively high random mixing degree to achieve “high disorder and densely packing”.

In some embodiments, the Cr—Zr—N alloy material satisfies the following two features:
an XRD pattern of the Cr—Zr—N alloy material has one or more peaks in a diffraction angle 2θ (°) range from 30 ° to 50 °, and a FWHM of at least one 2θ (°) diffraction peak in the range from 30 ° to 50 ° is greater than or equal to 2 °; and
a radial intensity profile corresponding to an SAED pattern of the Cr—Zr—N alloy material with characteristic interatomic spacing as a horizontal axis and diffraction intensity as a vertical axis, has one or more diffraction peaks in a range from 2.0 Å to 3.0 Å, and a FWHM of at least one of the diffraction peaks in the range from 2.0 Å to 3.0 Å is greater than or equal to 0.21 Å.

Further, the test results of XRD and the radial intensity profile corresponding to the SAED pattern of the Cr—Zr—N alloy material can also be referred to the description of the XRD pattern and the radial intensity profile corresponding to the SAED pattern of the Cr—Zr—N alloy coating, and the corresponding alternative and optional embodiments can also be applied to the Cr—Zr—N alloy material.

Some examples are provided below.

The embodiments of the present disclosure will be described in detail with reference to examples. It should be understood that these examples are merely for illustration of the present disclosure and are not intended to limit the scope of the present application. Experimental methods for which conditions are not specified in the following examples primarily refer to the guidelines given herein, or can be in accordance with experimental manuals or conventional conditions in the art, or can be in accordance with conditions suggested by the manufacturers, or can refer to experimental methods known in the art.

In the following examples, the measurement parameters relating to the raw material components can have slight deviations within the ranges of weighing accuracy, unless otherwise specified. Temperature and time parameters mentioned herein allow acceptable deviations caused by test accuracy or operational accuracy of the instruments,

### Test Method

### 1. Hardness Testing of Alloy Coating

During testing the hardness of the alloy coatings, the samples to be tested adopt substrates suitable for practical applications.

The surface materials of the “substrates suitable for practical applications” can include, but are not limited to, aluminum alloy, stainless-steel, and copper sheet.

In the following examples, unless otherwise specified, aluminum alloy substrates or stainless steel substrates are used for testing the hardness of the alloy coatings. The alloy coatings are deposited on aluminum alloy or stainless-steel with preset preparation parameters to obtain the samples to be tested for testing the hardness of the alloy coatings. This is mainly because, during the nanoindentation testing, when a probe penetrates into the sample, a strong pressure is formed and the substrate is required to have a certain toughness at this moment. Using a silicon wafer, which is more brittle, could lead to cracks during testing, resulting in inaccurate results. Alloy materials are more suitable as substrates for the nanoindentation testing due to their excellent toughness. Furthermore, using alloy materials as substrates to measure the nano-hardness is more universal for nano-hardness characterization in the field of coating.

The hardness of each film or coating is tested by NHT3 nanoindentation instrument manufactured by Anton-Paar from Austria, equipped with a tetrahedral Berkvich indenter. The indentation depth is set to 100 nm. The load changes with the indentation depth. Five matrix points on each sample are tested, and then the average value thereof is taken.

### 2. Corrosion Resistance Evaluation of Alloy Coating by Salt Spray Test

During corrosion resistance evaluation of the alloy coatings by salt spray test, substrates made from the same materials as used in practical applications are used for samples to test the extents to which the alloy coatings improve the corrosion resistance of the substrates. The surface materials of the “substrates made from the same materials as used in practical applications” can include, but are not limited to, aluminum alloy, and stainless-steel.

The testing follows the ASTM B117 salt spray test standard, wherein the pH value of the solution is in a range from 6.5 to 7.2, and the chemical composition of the solution is a combination of sodium chloride (NaCl), deionized water, and sodium hydroxide (NaOH).

A 12-hour period can be used as a sub-period for the corrosion resistance evaluation by salt spray test.

The test period for the alloy coatings on different substrate materials can vary, for example:

The test period for a sample with an aluminum alloy substrate is 48 hours or 24 hours.

The test period for a sample with a stainless-steel substrate is 144 hours or 96 hours.

The test period for a sample with a copper sheet substrate is 12 hour.

The standard for “passed (OK)” the corrosion resistance evaluation by salt spray test is that, after testing, the appearance of the sample shows no corrosion, no discoloration, and no rust.

The standard for “failed to pass (NG)” the corrosion resistance evaluation by salt spray test is that, after testing, the appearance of the sample shows corrosion, discoloration, or rust.

### 3. Morphological Observation and Compositional Analysis of Alloy Coating

The samples to be tested all adopt silicon wafers as substrates.

The testing involves scanning electron microscopy (SEM) and energy dispersive X-ray spectroscopy (EDX).

Morphology observation: A Hitachi Regulus 8230 scanning electron microscope is used.

Compositional analysis: An energy dispersive X-ray spectrometer (EDX) attached to the Hitachi Regulus 8230 scanning electron microscope is used, and the relative intensities of all elements are corrected by the ZAF method.

Test parameters: The acceleration voltage for the electrons is 15 kilovolts (kV), the beam current is 10 microamperes (μA), the magnification of the samples is 200 times, and ten points on each sample are tested, and then the average value thereof is taken.

In some SEM images, during the preparation of the cross-sectional samples for testing, some cross-sections show delamination formed during brittle fracturing silicon wafers, but this does not affect the observation and analysis of the cross-section morphology. The positions of different structural layers in the substrate and the protective coating can be determined according to the thickness of the respective structural layers.

### 4. XRD Characterization of Alloy Coating

During the XRD characterization of the alloy coatings, the substrates are silicon wafers.

### 4.1. Calculation of the FWHM Value of the Diffraction Peak in the XRD Pattern

A Bruker D8 Advance XRD diffractometer from Germany is used and operated in θ-2θ mode with Copper Kα radiation having a wavelength λ of 0.15406 nm. The X-ray tube is set to 40 kV and 40 mA, with a scanning range from 20° to 80° and a step size of 0.01° for precise scanning.

The steps of obtaining the FWHM value are: first correcting the diffraction peak, which can include smoothing, subtracting the background, removing the Kα2 lines, subtracting the instrument broadening, etc., and then fitting the diffraction peak with the Pseudo-Voigt function to obtain the FWHM value of the diffraction peak.

EDP2XRD software (version 1.0.0, copyright by Hongwei Liu, The Australian Center for Microscopy and Microanalysis, The University of Sydney) is used to process the raw data of the pattern as follows. Firstly, scale calibration is performed. Then the center of the transmission spot of the diffraction ring is determined. After that, the raw data is converted into an XRD pattern (wherein the electron wavelength is 0.00251 nm, the X-ray wavelength is 0.154 nm). Subsequently, the background is subtracted linearly from the diffraction peak, and then the result is fitted by the Voigt function to obtain the FWHM value of the corresponding diffraction peak.

### 4.2. Determination of the Formation of a Wide Peak in the XRD Pattern of Alloy Coating

The method for determining presence or absence of a wide peak within the diffraction angle 2θ (°) range from 30 ° to 50 ° in the XRD diffraction pattern is as follows: In the XRD pattern, a 2θ (°) diffraction peak is identified as a wide peak if the FWHM value of the diffraction peak is greater than or equal to 2°, and a 2θ (°) diffraction peak is identified as a sharp peak if the FWHM value of the diffraction peak is less than 2°.

At a specified 2θ(°) position, there can be no peak, a sharp peak, or a wide peak.

In the XRD patterns, the horizontal axis represents 2θ in unit of °; and the vertical axis represents the XRD intensity in unit of a.u. The radial intensity profiles are obtained according to the SAED patterns of the alloy coatings. The radial intensity profiles are expressed in the form of characteristic interatomic spacing (d)-diffraction intensity, with interatomic spacing (d) in unit of angstrom (Å) as the horizontal axis, and electron diffraction intensity (intensity) in unit of a.u. as the vertical axis.

In the XRD pattern and the radial intensity profile corresponding to the SAED pattern, “a.u.” has the well-known meaning in the art.

### 5. TEM Characterization

During the TEM characterization of the alloy coatings, the substrates are silicon wafers.

### 5.1. Methods for Obtaining the FWHM Data in the Diffraction Ring of the TEM Diffraction Pattern

TEM test sample preparation: The samples are thinned by using Helios 5 CX focused ion beam (FIB) from ThemoFisher Co., Ltd., USA, to obtain electronically transparent, TEM-observable planar samples.

SAED pattern acquisition: SAED patterns of the samples are obtained by using a Talos F200x transmission electron microscope (TEM) from ThemoFisher Co., Ltd., USA, with an electron acceleration voltage of 200 kV and a selected area aperture diameter of 900 nm.

Radial intensity profile acquisition: EDP2XRD software (version 1.0.0, copyright by Hongwei Liu, The Australian Center for Microscopy and Microanalysis, The University of Sydney) is used to process the raw data of the SAED pattern obtained above. First, scale calibration is performed. Then, the center of the transmission spot of the diffraction ring is determined. Finally, the raw data of the SAED pattern is converted into a radial intensity profile (wherein the electron wavelength is 0.00251 nanometers, and the X-ray wavelength is 0.154 nm), with the characteristic interatomic spacing as the horizontal axis and the diffraction intensity the vertical axis.

The steps of obtaining the FWHM value are as follows: The linear background is subtracted from the diffraction peak, and then the result is fitted by the Voigt function to obtain the FWHM value of the corresponding diffraction peak.

5.2. Method for determining presence or absence of a wide peak within the range from 2.0 Å to 3.0 Å in the radial intensity profile of the SAED pattern: A diffraction peak is identified as a wide peak if the FWHM value of the diffraction peak corresponding to the characteristic interatomic spacing is greater than or equal to 0.21 Å, and a diffraction peak is identified as a sharp peak if the FWHM value of the diffraction peak corresponding to the characteristic interatomic spacing is less than 0.21 Å. At a specific characteristic interatomic spacing, there can be in no peak, a sharp peak, or a wide peak.

### 6. Chromaticity Testing of Alloy Coating

During testing the chromaticity of the alloy coatings, substrates made from the same materials as used in practical applications are used for samples to test the extents to which the alloy coatings improve the compactness and other performances of the substrates. The surface materials of the “substrates made from the same materials as used in practical applications” can include, but are not limited to, aluminum alloy, and stainless steel.

The values of L, a and b of the samples are tested by using a CM-3700A-U desktop spectrophotometer manufactured by Konica, Japan. A F2 light source is selected for the light receiving system. Six matrix points on each sample are tested, and then the average value thereof is taken.

L represents luminance, a represents red or green chromaticity, and b represents yellow or blue chromaticity. The value of a represents red or green color of an object, where a positive value represents a red chromaticity value, and a negative value represents a green chromaticity value. The value of b represents yellow or blue color of an object, where a positive value represents a yellow chromaticity value, and a negative value represents a blue chromaticity value.

The greater the value of L, the higher the brightness, and the denser the coating surface. The mechanism is as follows: The spectrophotometer can create a reflectivity curve of light reflected from the surface of the test sample. The amplitude of this curve reflects the density of the material, which can be characterized by L. For the same material, the higher the compactness, the greater the value of L.

In all of the following examples, DI water represents deionized water.

In all of the following examples and comparative examples, the stainless-steel sheets, the aluminum alloy sheets, and the silicon wafers respectively have the same material.

In all of the following examples, the targets are sputtered by using a radio frequency assisted direct current sputtering method.

In the following examples, in the XRD patterns and the SAED-radial intensity profiles, “having one and only one wide peak” means that there is one and only one characteristic peak, and this peak is a wide peak, unless otherwise specified.

### EXAMPLE 1

In this example, the chemical composition of the Cr—Zr—N alloy coating is Cr_{53.8}Zr_{40.0}N_{6.2.}

Pretreatment: A stainless-steel sheet, an aluminum alloy sheet, and a silicon wafer, cach with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min. The dimension unit “mm” refers to “millimeter” and “cm” refers to “centimeter”.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 8 sccm and a flow rate ratio of Ar:N₂ of 6:1, while the chamber pressure is maintained at 0.7 Pa. A. bias voltage set to −100 V is applied, a power density for the Cr target is set to 4.2 W/cm² and a power density for the Zr target is set to 3.5 W/cm² to deposit the Cr—Zr—N alloy coatings each with a thickness of 2500 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{53.8}Zr_{40.0}N_{6.2}.

The hardness test result of the sample with the aluminum alloy substrate is 16.1 GPa, and the hardness test result of the sample with the stainless-steel substrate is 18.3 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

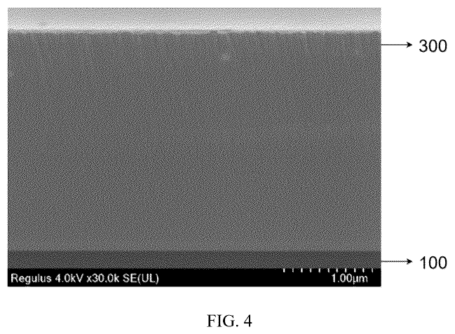

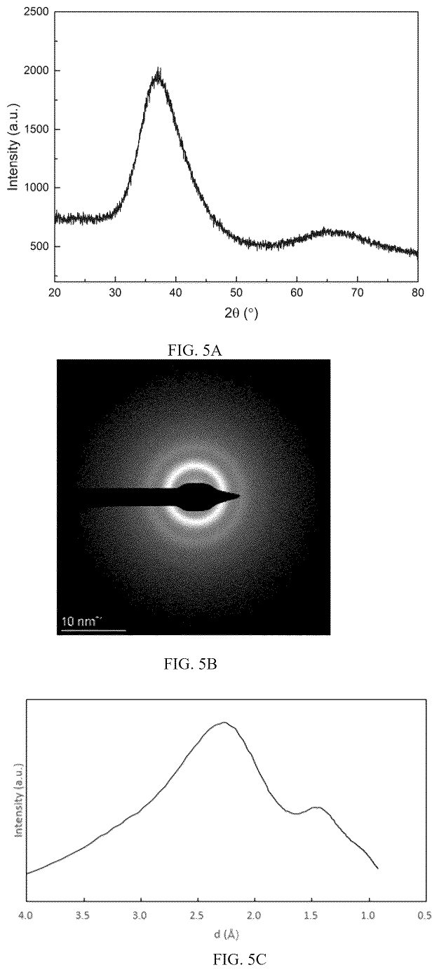

A cross-section of the test sample is subjected to SEM characterization, and the cross-sectional morphology can be seen in FIG. 4. The XRD diffraction pattern, SAED pattern, and radial intensity profile can be seen in FIGS. 5A to 5C. The SEM test result shows that the Cr—Zr—N alloy coating has a dense structure, and no penetrating columnar gaps are observed. The XRD test result shows that the XRD diffraction pattern has a wide peak within the diffraction angle 2θ (°) range from 30° to 50°, with the FWHM values all greater than or equal to 2° within the diffraction angle 2θ (°) range from 30° to 50°. Indeed, there is only one wide peak with the FWHM of 8.42° in the range from 30° to 50°. The radial intensity profile of SAED pattern has one and only one wide peak with the FWHM of 0.74 Å in the range from 2.0 Å to 3.0 Å.

Chromaticity test result: The chromaticity values of the sample with the aluminum alloy substrate are as follows: L equals 77.02, a equals 0.52, and b equals 4.99; the chromaticity values of the sample with the stainless-steel substrate are as follows: L equals 79.36, a equals 0.40, and b equals 4.49, showing a silvery-white color.

### EXAMPLE 2

In this example, the chemical composition of the Cr—Zr—N alloy coating is Cr_{34.5}Zr_{30.0}N_{35.5}, and the preparation method is as follows:

In this example, a Cr—Zr alloy target is used as the target, the Cr target 4 in FIG. 3 is replaced with the Cr—Zr alloy target with an atomic percentage ratio of Cr:Zr of 55%:45%.

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, and then kept at room temperature (about 30 °C) for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the Cr—Zr—N alloy coating: The sample table is turned on to rotate at a rotation speed of 6 rotations per minute. The distance from the sample table to the target surface is adjusted to 8 cm. The Cr—Zr target are energized by a radio frequency assisted DC power source. Ar and N₂ gases are introduced at a flow rate of N₂ gas of 42 sccm and a flow rate ratio of Ar:N₂ of 2:1, while the chamber pressure is maintained at 0.8 Pa. A bias voltage set to −100 V is applied, a power density for the Cr—Zr target is set to 5.0 W/cm² to deposit the Cr—Zr—N alloy coatings each with a thickness of 2000 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{34.5}Zr_{30.0}N_{35.5.}

The hardness test result of the sample with the aluminum alloy substrate is 21.7 GPa, and the hardness test result of the sample with the stainless-steel substrate is 22.1 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

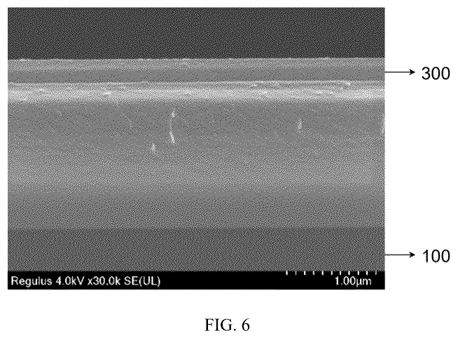

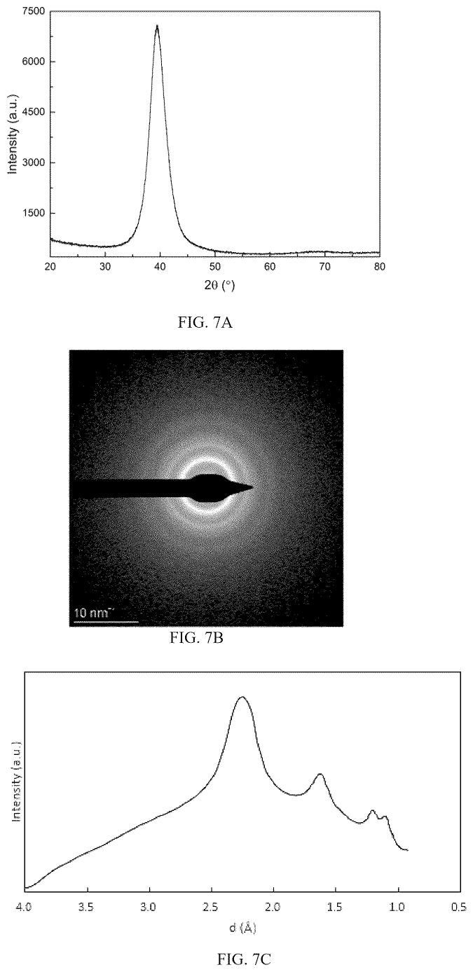

A cross-section of the test sample is subjected to SEM characterization, and the cross-sectional morphology can be seen in FIG. 6. The XRD diffraction pattern, SAED pattern, and radial intensity profile can be seen in FIGS. 7A to 7C. The SEM test result shows that the Cr—Zr—N alloy coating has a dense structure, and no penetrating columnar gaps are observed. The XRD test result shows that the XRD diffraction pattern has a wide peak within the diffraction angle 2θ (°) range from 30° to 50°, with the FWHM values all greater than or equal to 2° within the diffraction angle 2θ (°) range from 30° to 50°. Indeed, there is one and only one wide peak with the FWHM of 3.52° in the range from 30° to 50°. The radial intensity profile of SAED pattern has one and only one wide peak with the FWHM of 0.37 Å in the range from 2.0 Å to 3.0 Å.

Chromaticity test result: The chromaticity values of the sample with the aluminum alloy substrate are as follows: L equals 74.20, a equals 0.55, and b equals 7.68; the chromaticity values of the sample with the stainless-steel substrate are as follows: L equals 77.26, a equals 0.42, and b equals 7.11, showing a silvery-white color.

### EXAMPLE 3

In this example, the chemical composition of the Cr—Zr—N alloy coating is Cr_{15.0}Zr_{78.8}N_{6.2}, and the preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 8 sccm and a flow rate ratio of Ar:N₂ of 6:1, while the chamber pressure is maintained at 0.7 Pa. A bias voltage set to −100 V is applied, a power density for the Cr target is set to 1.3 W/cm² and a power density for the Zr target is set to 7.9 W/cm² to deposit the Cr—Zr—N alloy coatings each with a thickness of 2500 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{15.0}Zr_{78.8}N_{6.2.}

The hardness test result of the sample with the aluminum alloy substrate is 20.6 GPa, and the hardness test result of the sample with the stainless-steel substrate is 22.8 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

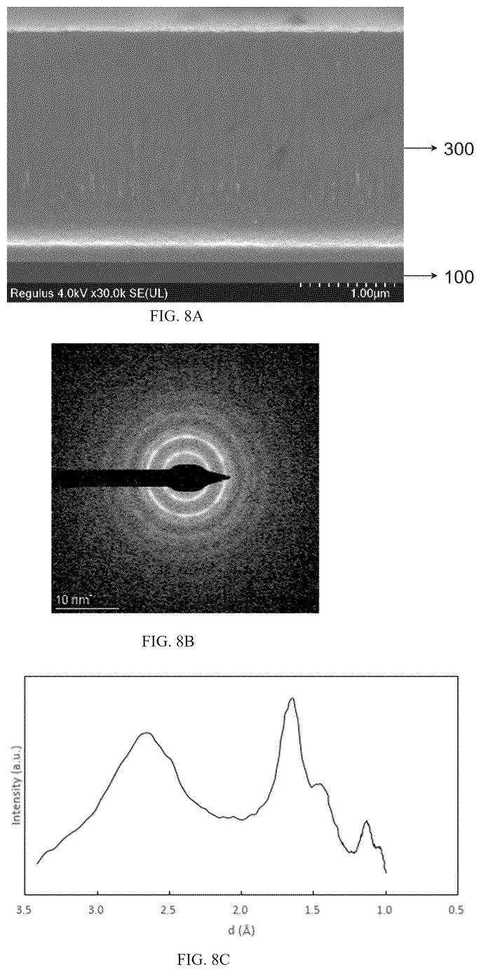

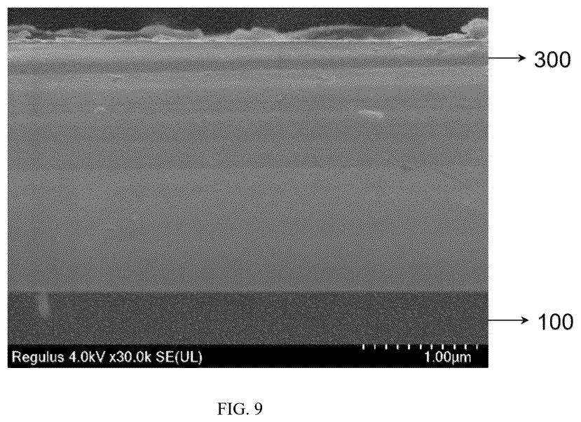

A cross-section of the test sample is subjected to SEM characterization, and the cross-sectional morphology, the SAED pattern, and the radial intensity profile can be seen in FIGS. 8A to 8C. The SEM test result shows that the Cr—Zr—N alloy coating has a dense structure, and no penetrating columnar gaps are observed. The XRD test result shows that the XRD diffraction pattern has a wide peak within the diffraction angle 2θ (°) range from 30° to 50°, with the FWHM values all greater than or equal to 2° within the diffraction angle 2θ (°) range from 30° to 50°. Indeed, there is one and only one wide peak with the FWHM of 3.92° in the range from 30° to 50°. The radial intensity profile of SAED pattern has one and only one wide peak with the FWHM of 0.41 Å in the range from 2.0 Å to 3.0 Å.

Chromaticity test result: The chromaticity values of the sample with the aluminum alloy substrate are as follows: L equals 74.29, a equals 0.53, and b equals 6.38; the chromaticity values of the sample with the stainless-steel substrate are as follows: L equals 75.65, a equals 0.47, and b equals 6.31, showing a silvery-white color.

### EXAMPLE 4

In this example, the chemical composition of the Cr—Zr—N alloy coating is Cr_{15.0}Zr_{49.5}N_{35.5}, and the preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 42 sccm and a flow rate ratio of Ar:N₂ of 2:1, while the chamber pressure is maintained at 0.8 Pa. A bias voltage set to −100 V is applied, a power density for the Cr target is set to 1.3 W/cm² and a power density for the Zr target is set to 5 W/cm² to deposit the Cr—Zr—N alloy coatings each with a thickness of 2200 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{15.0}Zr_{49.5}N_{35.5}.

The hardness test result of the sample with the aluminum alloy substrate is 21.2 GPa, and the hardness test result of the sample with the stainless-steel substrate is 22.6 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

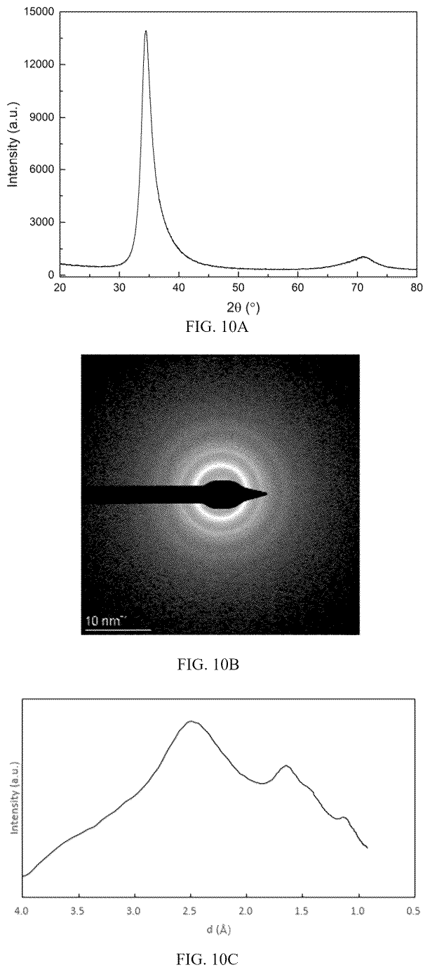

A cross-section of the test sample is subjected to SEM characterization, and the cross-sectional morphology can be seen in FIG. 9. The XRD diffraction pattern, SAED pattern, and radial intensity profile can be seen in FIGS. 10A to 10C. The SEM test result shows that the Cr—Zr—N alloy coating has a dense structure, and no penetrating columnar gaps are observed. The XRD test result shows that the XRD diffraction pattern has a wide peak within the diffraction angle 2θ (°) range from 30° to 50°, with the FWHM values all greater than or equal to 2° within the diffraction angle 2θ (°) range from 30° to 50°. Indeed, there is one and only one wide peak with the FWHM of 2.23° in the range from 30° to 50°. The radial intensity profile of SAED pattern has one and only one wide peak with the FWHM of 0.73 Å in the range from 2.0 Å to 3.0 Å.

Chromaticity test result: The chromaticity values of the sample with the aluminum alloy substrate are as follows: L equals 75.25, a equals 0.52, and b equals 6.48; the chromaticity values of the sample with the stainless-steel substrate are as follows: L equals 76.95, a equals 0.41, and b equals 60.4, showing a silvery-white color.

### EXAMPLE 5

In this example, the chemical composition of the Cr—Zr—N alloy coating is Cr_{29.7}Zr_{50.1}N_{20.2}, and the preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10−4 Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 24 sccm and a flow rate ratio of Ar:N₂ of 3:1, while the chamber pressure is maintained at 0.6 Pa. A bias voltage set to −100 V is applied, a power density for the Cr target is set to 2.6 W/cm² and a power density for the Zr target is set to 5 W/cm² to deposit the Cr—Zr—N alloy coatings each with a thickness of 2500 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{29.7}Zr_{50.1}N_{20.2.}

The hardness test result of the sample with the aluminum alloy substrate is 19.5 GPa, and the hardness test result of the sample with the stainless-steel substrate is 21.7 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

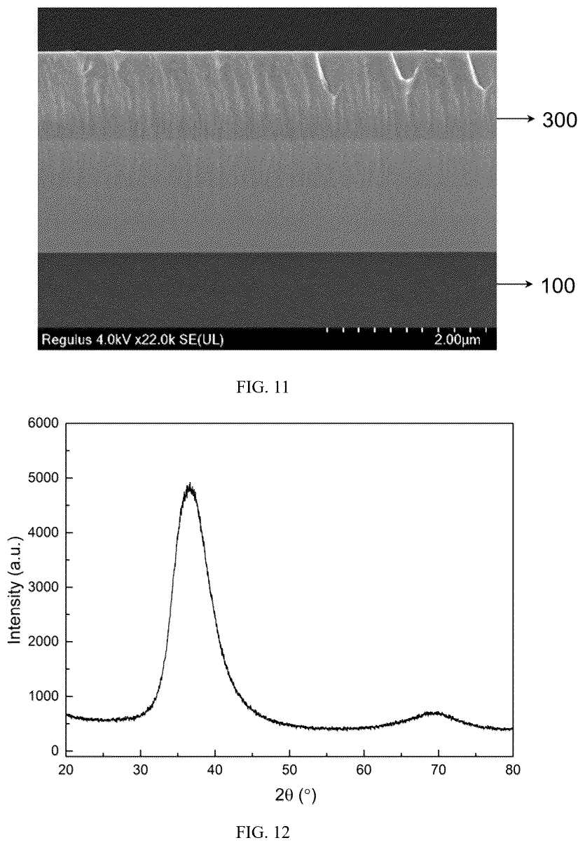

A cross-section of the test sample is subjected to SEM characterization, and the cross-sectional morphology can be seen in FIG. 11. The XRD diffraction pattern can be seen in FIG. 12. The SEM test result shows that the Cr—Zr—N alloy coating has a dense structure, and no penetrating columnar gaps are observed. The XRD test result shows that the XRD diffraction pattern has a wide peak within the diffraction angle 2θ (°) range from 30° to 50°, with the FWHM values all greater than or equal to 2° within the diffraction angle 2θ (°) range from 30° to 50°. Indeed, there is one and only one wide peak with the FWHM of 5.66° in the range from 30° to 50°. The radial intensity profile of SAED pattern has at least one wide peak in the range from 2.0 Å to 3.0 Å.

Chromaticity test result: The chromaticity values of the sample with the aluminum alloy substrate are as follows: L equals 76.13, a equals 0.52, and b equals 5.88; the chromaticity values of the sample with the stainless-steel substrate are as follows: L equals 78.01, a equals 0.42, and b equals 5.07, showing a silvery-white color.

### EXAMPLE 6

In this example, a double-layer film structure is coated on the surface of the substrate, including a Cr—Zr—N alloy coating with the chemical composition of Cr_{15.0}Zr_{78.8}N_{6.2} and a surface layer with the chemical composition of TiN. The double-layer film structure is recorded as Cr—Zr—N/TIN. As such, a multiple-layer film structure is coated on the surface of the substrate, where the Cr—Zr—N alloy coating provided by the present disclosure serves as an intermediate layer, being located between the substrate and the surface layer. The preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150°C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 8 sccm and a flow rate ratio of Ar:N₂ of 6:1, while the chamber pressure is maintained at 0.7 Pa. A bias voltage set to −100 V is applied, a power density for the Cr target is set to 1.3 W/cm² and a power density for the Zr target is set to 7.9 W/cm² to deposit the Cr—Zr—N alloy coatings each with a thickness of 1000 nm by controlling the deposition time.

Deposition of the surface layer: the Zr target in the chamber is replaced with a Ti target, the sample table turntable is turned on to rotate at a rotation speed of 6 rotations per minute. The distance from the sample table to the target surface to is adjusted to 8 cm. The Ti target is energized by DC power source. Ar and N₂ gases are introduced at a flow rate of the N₂ gas of 10 sccm and a flow rate ratio of Ar:N₂ of 3:1, while the chamber pressure is maintained at 0.5 Pa. A bias voltage set to −100 V is applied, the power density for the Ti target is set to 5 W/cm² to deposit the TiN coatings each with a thickness of 100 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the surface of the alloy coating with the composition of Cr_{15.0}Zr_{78.8}N_{6.2} is coated with the TiN coating as the surface layer.

The hardness test result of the sample with the aluminum alloy substrate is 12.2 GPa, and the hardness test result of the sample with the stainless-steel substrate is 14.5 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

A cross-section of the test sample is subjected to SEM characterization, and the SEM test result shows that the Cr—Zr—N alloy coating has a dense structure.

Chromaticity test result: The chromaticity values of the sample with the aluminum alloy substrate are as follows: L equals 55.75, a equals 6.65, and b equals 12.92; the chromaticity values of the sample with the stainless-steel substrate are as follows: L equals 56.23, a equals 6.82, and b equals 13.21, showing a golden-yellow color.

### EXAMPLE 7

In this example, a three-layer film structure is coated on the surface of the substrate, including a transition layer (as a bottom coating), a Cr—Zr—N alloy coating containing a Cr—Zr—N alloy material, and a surface layer located on the surface in sequence from the surface of the substrate. The three-layer film structure is recorded as Cr/Cr—Zr—N/TIN, where the transition layer is a Cr layer, the chemical composition of the Cr—Zr—N alloy coating is Cr_{15.0}Zr_{78.8}N_{6.2} and the chemical composition of the surface layer is TiN. The preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the bottom coating (the transition layer): The sample table turntable is turned on to rotate at a rotation speed of 6 rotations per minute. The distance from the sample table to the target surface to is adjusted to 8 cm. The Cr target is energized by radio frequency assisted DC power source. Ar gas is introduced at a flow rate of 42 sccm, while the chamber pressure is maintained at 0.5 Pa. A bias voltage set to −100 V is applied, a power density for the Cr target is set to 5 W/cm² to deposit the Cr bottom coating with a thickness of 300 nm by controlling the deposition time.

Deposition of the Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 8 sccm and a flow rate ratio of Ar:N₂ of 6:1, while the chamber pressure is maintained at 0.7 Pa. A bias voltage set to −100 V is applied, a power density for the Cr target is set to 1.3 W/cm² and a power density for the Zr target is set to 7.9 W/cm² to deposit the Cr—Zr—N alloy coatings with a thickness of 1000 nm by controlling the deposition time.

Deposition of the surface layer: the Zr target in the chamber is replaced with a Ti target, the sample table turntable is turned on to rotate at a rotation speed of 6 rotations per minute. The distance from the sample table to the target surface to is adjusted to 8 cm. The Ti target is energized by DC power source. Ar and N₂ gases are introduced at a flow rate of the N₂ gas of 10 sccm and a flow rate ratio of Ar:N₂ of 3:1, while the chamber pressure is maintained at 0.5 Pa. A bias voltage set to −100 V is applied, the power density for the Ti target is set to 5 W/cm² to deposit the TiN coating with a thickness of 100 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the three-layer film structure is coated on the surface of the substrate, and the chemical compositions are Cr (the transition layer), Cr_{15.0}Zr_{78.8}N_{6.2} (an embodiment of the Cr—Zr—N alloy coating of the present disclosure) and TiN (the surface layer) in sequence, and the three-layer film structure is recorded as Cr/Cr—Zr—N/TiN.

The hardness test result of the sample with the aluminum alloy substrate is 13.8 GPa, and the hardness test result of the sample with the stainless-steel substrate is 15.4 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

A cross-section of the test sample is subjected to SEM characterization, and the SEM test result shows that the Cr—Zr—N alloy coating has a dense structure.

Chromaticity test result: The chromaticity values of the sample with the aluminum alloy substrate are as follows: L equals 53.49, a equals 7.07, and b equals 13.81; the chromaticity values of the sample with the stainless-steel substrate are as follows: L equals 55.73, a equals 7.35, and b equals 14.50, showing a golden-yellow color.

### EXAMPLE 8

In this example, the chemical composition of the Cr—Zr—N alloy coating is Cr_{15.0}Zr_{78.8}N_{6.2}, and the preparation method is as follows:

Pretreatment: A copper sheet and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 8 sccm and a flow rate ratio of Ar:N₂ of 6:1, while the chamber pressure is maintained at 0.7 Pa. A bias voltage set to −100 V is applied, a power density for the Cr target is set to 1.3 W/cm² and a power density for the Zr target is set to 7.9 W/cm² to deposit the Cr—Zr—N alloy coatings each with a thickness of 1000 nm by controlling the deposition time.

The sample with the copper sheet as the substrate is subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{15.0}Zr_{78.8}N_{6.2}. The hardness test result of the sample with the copper substrate is 8.9 GPa. In the corrosion resistance evaluation by salt spray test, the sample with the copper substrate can pass the 12-hour test, exhibiting a certain protective performance.

The SEM test result shows that the alloy coating has a dense structure, and no penetrating columnar gaps are observed.

The sample with the copper substrate is subjected to Chromaticity testing, and the chromaticity values are as follows: L equals 74.78, a equals 0.56, and b equals 6.58, showing a silvery-white color.

### EXAMPLE 9

### The Cr—Zr—N Alloy Coating with a Thickness of about 50 nm

The method is basically the same as that in Example 5, with the chemical composition of the Cr—Zr—N alloy coating being Cr_{29.7}Zr_{50.1}N_{20.2}, except that the thickness of the Cr—Zr—N alloy coating is adjusted to 50 nm.

The hardness value of the sample with the aluminum alloy substrate is 9.1 GPa, and the hardness value of the sample with the stainless-steel substrate is 9.8 GPa. In the salt spray corrosion resistance test, the sample with the aluminum alloy substrate can pass the 48-hour test, and the sample with the stainless-steel substrate can pass the 144-hour test, exhibiting excellent protective performances.

Chromaticity test result: The chromaticity values of the sample with the aluminum alloy substrate are as follows: L equals 77.23, a equals 0.51, b equals 5.98. The chromaticity values of the sample with the stainless-steel substrate are as follows: L equals 78.81, a equals 0.41, and b equals 5.27, showing a silvery-white color.

### EXAMPLE 10

### The Cr—Zr—N Alloy Coating with a Thickness of about 6 μm

The method is basically the same as that in Example 5, with the chemical composition of the Cr—Zr—N alloy coating being Cr_{29.7}Zr_{50.1}N_{20.2}, except that the thickness of the Cr—Zr—N alloy coating is adjusted to 6000 nm.

The hardness value of the sample with the aluminum alloy substrate is 23.8 GPa, and the hardness value of the sample with the stainless-steel substrate is 25.2 GPa. In the salt spray corrosion resistance test, the sample with the aluminum alloy substrate can pass the 48-hour test, and the sample with the stainless-steel substrate can pass the 144-hour test, exhibiting an excellent protective performance.

Chromaticity test result: The chromaticity values of the sample with the aluminum alloy substrate are as follows: L equals 75.23, a equals 0.55, b equals 6.08. The chromaticity values of the sample with the stainless-steel substrate are as follows: L equals 76.81, a equals 0.42, and b equals 5.57, showing a silvery-white color.

### EXAMPLE 11

### Containing a Doping Element

In this example, the chemical composition of the Cr—Zr—N alloy coating containing a doping element is Cr_{34.5}Zr_{30.0}N_{35.5}C₅. The normalization is performed based on the total atomic ratio of Cr, Zr, and N being 100. The atomic ratio of Cr, Zr, and N is about 36.32:31.58:32.11, and the atomic percentage of the doping element C in the Cr—Zr—N alloy coating is 5%. The preparation method is as follows:

In this example, a Cr—Zr alloy target is used as the target, the Cr target 4 in FIG. 3 is replaced with the Cr—Zr alloy target with an atomic percentage ratio of Cr:Zr of 55%:45%.

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the Cr—Zr—N alloy coating: The sample table is turned on to rotate at a rotation speed of 6 rotations per minute. The distance from the sample table to the target surface is adjusted to 8 cm. The Cr—Zr target is energized by a radio frequency assisted DC power source. Ar, C₂H₂ and N₂ gases are introduced at a flow rate of N₂ gas of 35 sccm, a flow rate of C₂H₂ gas of 6 sccm, and a flow rate ratio of Ar: (C₂H₂+N₂) of 2:1, while the chamber pressure is maintained at 0.8 Pa. A bias voltage set to −100 V is applied, a power density for the Cr—Zr target is set to 4.5 W/cm² to deposit the Cr—Zr—N alloy coatings (the Cr—Zr—N alloy coatings doped with carbon) each with a thickness of 2500 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{34.5}Zr_{30.0}N_{30.5}C₅.

The hardness test result of the sample with the aluminum alloy substrate is 21.2 GPa, and the hardness test result of the sample with the stainless-steel substrate is 21.8 GPa. In the corrosion resistance evaluation by salt spray test, the sample with the aluminum alloy substrate can pass the 48-hour test, and the sample with the stainless-steel substrate can pass the 144-hour test, exhibiting excellent protective performances.

The XRD diffraction pattern has at least one wide peak within the diffraction angle 2θ (°) range from 30° to 50°. The radial intensity profile of SAED pattern has at least one wide peak in the range from 2.0 Å to 3.0 Å.

Chromaticity test result: The chromaticity values of the sample with the aluminum alloy substrate are as follows: L equals 73.8, a equals 0.59, and b equals 6.78; the chromaticity values of the sample with the stainless-steel substrate are as follows: L equals 76.16, a equals 0.42, and b equals 6.71, showing a silvery-white color.

According to the experimental results explored by the inventors, when other non-metal doping elements (such as Si, B, O, etc.) or metal doping elements (such as Al) are employed, at appropriate atomic ratios (such as 4 at %, 2 at %) of the doping elements, relatively high hardness and excellent corrosion resistance can also be achieved. In some embodiments, in the salt spray corrosion resistance test, the sample with the aluminum alloy substrate can pass the 48-hour test, and the sample with the stainless-steel substrate can pass the 144-hour test. The XRD diffraction pattern has at least one wide peak at diffraction angle 2θ (°) range from 30° to 50°, and the radial intensity profile of the SAED pattern has at least one wide peak in the range from 2.0 Å to 3.0 Å.

“At %” refers to atomic percentage, and is measured in quantity.

### EXAMPLE 12

In this example, the chemical composition of the Cr—Zr—N alloy coating is Cr_{53.8}Zr₃₀N_{16.2}, which does not satisfy the following formulas: 64.5-y≤x≤93.8-y, and 15.0≤x≤1.93y-23.4.

The preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150°C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 18 sccm and a flow rate ratio of Ar:N₂ of 3:1, while the chamber pressure is maintained at 0.7 Pa. A bias voltage set to −100 V is applied, a power density for the Cr target is set to 4.5 W/cm², a power density for the Zr target is set to 2.7 W/cm² to deposit the Cr—Zr—N alloy coatings each with a thickness of 1000 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{53.8}Zr₃₀N_{16.2}.

The hardness test result of the sample with the aluminum alloy substrate is 11.1 GPa, and the hardness test result of the sample with the stainless-steel substrate is 12.3 GPa. In the corrosion resistance evaluation by salt spray test, the sample with the aluminum alloy substrate can pass the 24-hour test (fails to pass the 48-hour test), and the sample with the stainless-steel substrate can pass the 96-hour test (fails to pass the 144-hour test), exhibiting good but not excellent protective performances.

The XRD diffraction pattern has at least one wide peak within the diffraction angle 2θ (°) range from 30° to 50°. The radial intensity profile of SAED pattern has at least one wide peak in the range from 2.0 Å to 3.0 Å.

Chromaticity test result: The chromaticity values of the sample with the aluminum alloy substrate are as follows: L equals 77.52, a equals 0.68, and b equals 4.12; the chromaticity values of the sample with the stainless-steel substrate are as follows: L equals 79.34, a equals 0.51, and b equals 3.74, showing a silvery-white color.

In addition, according to the experimental results explored by the inventors, the Cr—Zr—N alloy coating of the present disclosure has high hardness and excellent corrosion resistance when the following two conditions are both satisfied: (1) the XRD diffraction pattern has at least one wide peak in the diffraction angle 2θ (°) range from 30° to 50°, and (2) the radial intensity profile of the SAED pattern has at least one wide peak in the range from 2.0 Å to 3.0 Å. If only the feature of the XRD diffraction pattern having at least one wide peak in the diffraction angle 2θ (°) range from 30° to 50° is satisfied, but no wide peak can be found in the radial intensity profile of the SAED pattern in the range from 2.0 Å to 3.0 Å, the prepared Cr—Zr—N alloy coating may exhibit poor corrosion resistance, for example, the corresponding sample with the aluminum alloy substrate may fail to pass the 24-hour salt spray corrosion resistance. Conversely, if the radial intensity profile of the SAED pattern has at least one wide peak in the range of 2.0 Å to 3.0 Å, but the XRD diffraction pattern has no wide peak in the diffraction angle 2θ (°) range from 30° to 50°, the Cr—Zr—N alloy coating may also exhibit poor corrosion resistance, see Comparative Example 4 below.

### Comparative Example 1

In this comparative example, the chemical composition of the alloy coating is Cr_{88.9}Zr_{11.1}, and the preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the Cr—Zr alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar gas is introduced, while the chamber pressure is maintained at 0.6 Pa. A bias voltage set to −100 V is applied, a power density for the Cr target is set to 6.7 W/cm² and a power density for the Zr target is set to 0.8 W/cm² to deposit the Cr—Zr alloy coatings each with a thickness of 1900 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization and the compositional analysis.

The compositional analysis confirms that the composition of the alloy coating on the surface of the substrate is Cr_{88.9}Zr_{11.1}.

The hardness test result of the sample with the aluminum alloy substrate is 18.5 GPa, and the hardness test result of the sample with the stainless-steel substrate is 19.6 GPa. In the corrosion resistance evaluation by salt spray test, the sample with the aluminum alloy substrate fail to pass the 48-hour test (NG, protection duration time <24 h), and the sample with the stainless-steel substrate fail to pass the 144-hour test (NG, protection duration time <48 h), exhibiting poor protective performances.

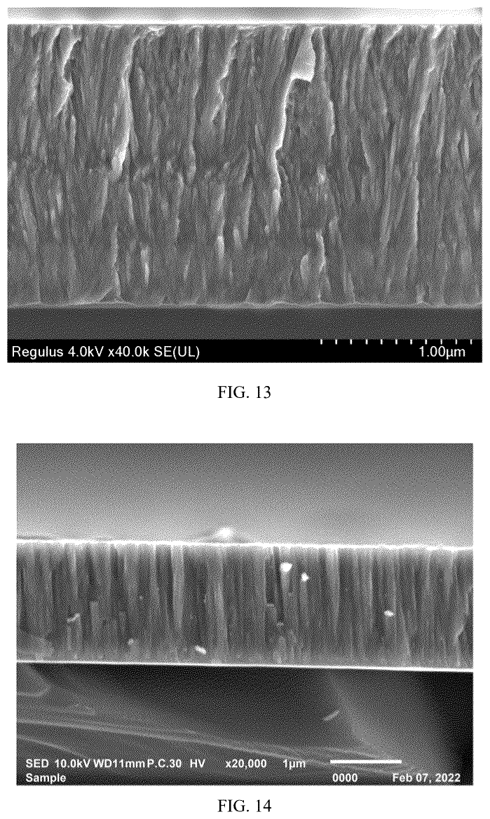

A cross-section of the test sample is subjected to SEM characterization, and the cross-sectional morphology can be seen in FIG. 13. The SEM test result shows that the alloy coating has crystal defects and an uncompact structure, and significant gaps are observed.

Chromaticity test result: The chromaticity values of the sample with the aluminum alloy substrate are as follows: L equals 83.21, a equals −0.21, and b equals 0.88; the chromaticity values of the sample with the stainless-steel substrate are as follows: L equals 85.05, a equals- 0.25, and b equals 0.79, showing a silvery-white color.

### Comparative Example 2

In this comparative example, the chemical composition of the Cr—Zr—N alloy coating is Cr_{37.8}Zr_{16.2}N₄₆, and the preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the Cr—Zr—N alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 52 sccm and a flow rate ratio of Ar:N₂ of 2:1, while the chamber pressure is maintained at 0.9 Pa. A bias voltage set to −100 V is applied, a power density for the Cr target is set to 3.5 W/cm² and a power density for the Zr target is set to 1.8 W/cm² to deposit the Cr—Zr—N alloy coatings each with a thickness of 1000 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{37.8}Zr_{16.2}N₄₆.

The hardness test result of the sample with the aluminum alloy substrate is 16.6 GPa, and the hardness test result of the sample with the stainless-steel substrate is 18.1 GPa. In the corrosion resistance evaluation by salt spray test, the sample with the aluminum alloy substrate fails to pass the 48-hour test (NG, protection duration time <24 h), and the sample with the stainless steel substrate fails to pass the 144-hour test (NG, protection duration time <48 h), exhibiting poor protective performances.

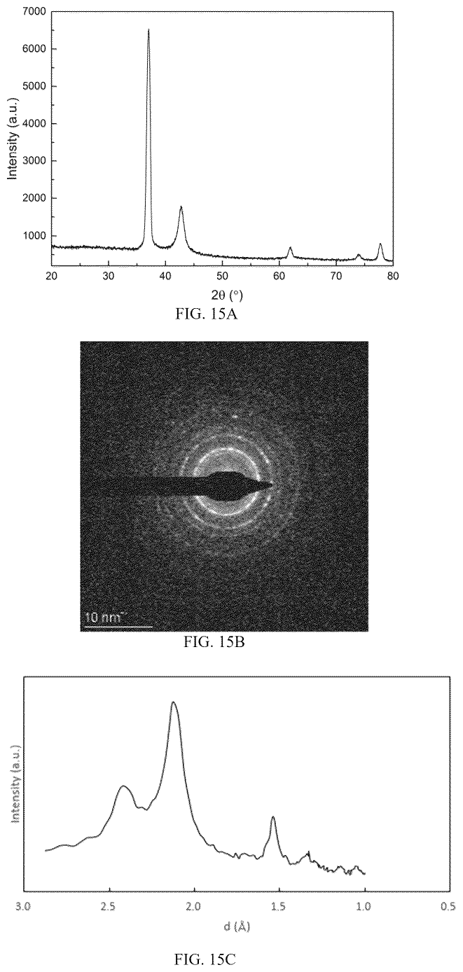

A cross-section of the test sample is subjected to SEM characterization, and the cross-sectional morphology can be seen in FIG. 14. The XRD diffraction pattern, SAED pattern, and radial intensity profile can be seen in FIGS. 15A to 15C. The SEM test result shows that the alloy coating has a loose structure, and significant penetrating columnar gaps are observed. The XRD test result shows that the XRD diffraction pattern has two peaks, which are both sharp peaks (i.e., the 2θ peaks with the FWHM values of less than 2°), in the diffraction angle 2θ (*) range from 30° to 50°, wherein the FWHM values of the two sharp peaks in the range from 30° to 50° are 0.66° and 1.24°, respectively. The radial intensity profile of the SAED pattern has two peaks with the FWHM values of 0.13 Å and 0.18 Å, respectively, in the range from 2.0 Å to 3.0 Å, i.e., the two peaks are sharp peaks.

Chromaticity test result: The chromaticity values of the sample with the aluminum alloy substrate are as follows: L equals 61.87, a equals 0.57, and b equals 4.45. The chromaticity values of the sample with the stainless-steel substrate are as follows: L equals 67.38, a equals 0.49, and b equals 4.29, showing a dull color without metal luster.

### Comparative Example 3

In this comparative example, the film structure is TIN, the chemical composition of the alloy coating is TiN.

In order to form the coating of the present comparative example, the Zr target in the chamber is replaced with a Ti target, and the preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the TiN coating: The sample table is turned on to rotate at a rotation speed of 6 rotations per minute. The distance from the sample table to the target surface is adjusted to 8 cm. The Ti target is energized by a radio frequency assisted DC power source. Ar and N₂ gases are introduced at a flow rate of N₂ gas of 10 sccm and a flow rate ratio of Ar: N₂ of 3:1, while the chamber pressure is maintained at 0.5 Pa. A bias voltage set to −100 V is applied, a power density for the Ti target is set to 5 W/cm² to deposit the TiN alloy coatings each with a thickness of 200 nm by controlling the deposition time.

The samples respectively with the stainless-steel sheet and the aluminum alloy sheet as the substrates are subjected to the corrosion resistance evaluation by salt spray test, the hardness testing, and the chromaticity testing.

The compositional analysis confirms that the composition of the alloy coating on the surface of the substrate is TiN.

The hardness test result of the sample with the aluminum alloy substrate is 3.8 GPa, and the hardness test result of the sample with the stainless-steel substrate is 4.3 GPa. In the corrosion resistance evaluation by salt spray test, the sample with the aluminum alloy substrate fail to pass the 48-hour test (NG, protection duration time <12 h), and the sample with the stainless-steel substrate fail to pass the 144-hour test (NG, protection duration time <24 h).

Chromaticity test result: The chromaticity values of the sample with the aluminum alloy substrate are as follows: L equals 57.95, a equals 6.45, and b equals 13.95; the chromaticity values of the sample with the stainless-steel substrate are as follows: L equals 59.33, a equals 6.92, and b equals 13.91, showing a golden-yellow color.

### Comparative Example 4

In this comparative example, the chemical composition of the alloy coating is Cr_{39.6}Zr_{19.4}N₄₁, and the preparation method is as follows:

Pretreatment: A stainless-steel sheet, an aluminum alloy sheet, and a silicon wafer, each with a length-width size of 50 mm×50 mm, are respectively put into deionized water and subjected to ultrasonic cleaning for 15 min, dried in a baking oven, and then put into the vacuum chamber of the film deposition device. The vacuum chamber is vacuumized to 5×10⁻⁴ Pa, heated to 150 °C, and then kept at 150 °C for 15 min.

Plasma cleaning: Ar gas is introduced, the pressure in the chamber is maintained at 2.0 Pa, and a bias voltage of −800 V is applied. The samples after the pretreatment are subjected to plasma cleaning for 20 min, so as to remove trace impurities on the sample surfaces by plasma etching.

Deposition of the alloy coating: The sample table is turned on to rotate at a rotation speed of 6 rotations per minute. The distance from the sample table to the target surface is adjusted to 8 cm. The Cr target and Zr target are energized by a radio frequency assisted DC power source. Ar and N₂ gases are introduced at a flow rate of N₂ gas of 45 sccm and a flow rate ratio of Ar:N₂ of 2:1, while the chamber pressure is maintained at 0.8 Pa. A bias voltage set to −100 V is applied, a power density for the Cr target is set to 4.6 W/cm² and a power density for the Zr target is set to 2.2 W/cm² to deposit the Cr—Zr—N alloy coatings each with a thickness of 1400 nm by controlling the deposition time.

The samples respectively with the stainless-steel sheet and the aluminum alloy sheet as the substrates are subjected to the corrosion resistance evaluation by salt spray test, the hardness testing, and the chromaticity testing, and the sample with the silicon wafer as the substrate is subjected to the SEM characterization, the compositional analysis, the XRD analysis, and the TEM characterization.

The compositional analysis confirms that the composition of the alloy coating on the surface of the substrate is Cr_{39.6}Zr_{19.4}N₄₁.

The hardness test result of the sample with the aluminum alloy substrate is 15.4 GPa, and the hardness test result of the sample with the stainless-steel substrate is 17.2 GPa. In the corrosion resistance evaluation by salt spray test, the sample with the aluminum alloy substrate fails to pass the 48-hour test (NG, protection duration time <12 h), and the sample with the stainless-steel substrate fails to pass the 144-hour test (NG, protection duration time <24 h), exhibiting no protective performances to the substrates.

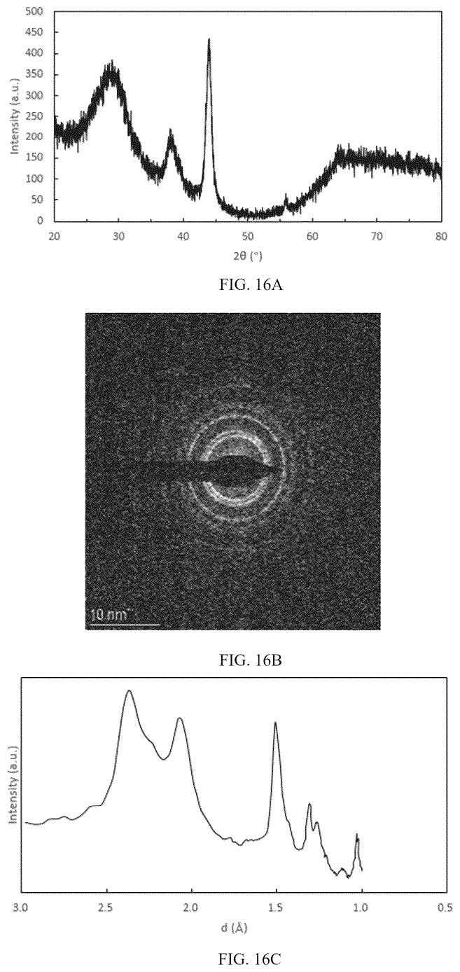

The SEM test result shows that the alloy coating has crystal defects and an uncompact structure, and significant penetrating columnar gaps are observed. The XRD diffraction pattern, SAED pattern, and radial intensity profile of the alloy coating can be seen in FIGS. 16A to 16C. The XRD test result shows that the XRD diffraction pattern has two peaks, which are both sharp peaks (i.e., the 2θ peaks with the FWHM values of less than 2°), in the diffraction angle 2θ (°) range from 30° to 50°, wherein the FWHM values of the two sharp peaks in the range from 35° to 40° are 1.87° and 1.02°, respectively. The radial intensity profile of the SAED pattern has two peaks with the FWHM values of 0.18 Å and 0.21 Å, respectively, in the range from 2.0 Å to 3.0 Å, i.e., one of them is a sharp peak.

Chromaticity test result: The chromaticity values of the sample with the aluminum alloy substrate are as follows: L equals 64.71, a equals 0.58, and b equals 4.15; the chromaticity values of the sample with the stainless-steel substrate are as follows: L equals 66.38, a equals 0.49, and b equals 4.27, showing a silver-white color.

### Comparative Example 5

### The Alloy Coating with a Thickness of 50 nm

The method is basically the same as that in Comparative Example 4, with the chemical composition of the alloy coating being Cr_{39.6}Zr_{19.4}N₄₁, except that the thickness of the alloy coating is different and is changed to 50 nm from 1400 nm.

The hardness values of the sample with the aluminum alloy substrate is 9.1 GPa, and the hardness values of the sample with the stainless-steel substrate is 9.8 GPa. In the salt spray corrosion resistance test, the sample with aluminum alloy substrate fails to pass the 48-hour test (NG, protection duration time <12 h), and the sample with stainless-steel substrate fails to pass the 144-hour test (NG, protection duration time <24 h), having no protective effect on the substrates.

### Comparative Example 6

### The Alloy Coating with a Thickness of 1000 nm

The method is basically the same as that in Comparative Example 4, with the chemical composition of the alloy coating being Cr_{39.6}Zr_{19.4}N₄₁, except that the thickness of the alloy coating is different and is changed to 1000 nm from 1400 nm.

The hardness value of the sample with the aluminum alloy substrate is 16.5 GPa, and the hardness value of the sample with the stainless-steel substrate is 17.9 GPa. In the salt spray corrosion resistance test, the sample with the aluminum alloy substrate fails to pass the 48-hour test (NG, protection duration time <12 h), and the sample with the stainless-steel sheet substrate fails to the 144-hour test (NG, protection duration time <24 h), having no protective effect on the substrates.

### Comparative Example 7

### The Alloy Coating with a Thickness of 2500 nm

The method is basically the same as that in Comparative Example 4, with the chemical composition of the alloy coating being Cr_{39.6}Zr_{19.4}N₄₁, except that the thickness of the alloy coating is different and is changed to 2500 nm from 1400 nm.

The hardness value of the sample with the aluminum alloy substrate is 20.5 GPa, and the hardness value of the sample with the stainless-steel substrate is 21.1 GPa. In the salt spray corrosion resistance test, the sample with the aluminum alloy substrate fails to pass the 48-hour test (NG, protection duration time <12 h), and the sample with the stainless-steel substrate fails to pass the 144-hour test (NG, protection duration time <24 h), having no protective effect on the substrates.

### Comparative Example 8

### The Alloy Coating with a Thickness of 6000 nm

The method is basically the same as that in Comparative Example 4, with the chemical composition of the alloy coating being Cr_{39.6}Zr_{19.4}N₄₁, except that the thickness of the alloy coating is different and is changed to 6000 nm from 1400 nm.

The hardness value of the sample with the aluminum alloy substrate is 22.1 GPa, and the hardness value of the sample with the stainless-steel substrate is 23.7 GPa. In the salt spray corrosion resistance test, the sample with the aluminum alloy substrate fails to pass the 48-hour test (NG, protection duration time <12 h), and the sample with the stainless-steel substrate fails to pass the 144-hour test (NG, protection duration time <24 h), having no protective effect on the substrates.

### Comparative Examples 9 to 11

### Without Protective Coating

A Stainless-steel bare sheet, an aluminum alloy bare sheet, and a copper bare sheet are subjected to the corrosion resistance evaluation by salt spray test, respectively. As a result, significant corrosion occurs within 12 hours.

### Result Analysis

The Cr—Zr—N alloy coatings provided by the present disclosure satisfy a certain atomic ratio of Cr, Zr, and N elements, being rich in Zr.

The Cr—Zr—N alloy coatings (Examples 1 to 12) provided by the present disclosure can be used as protective coatings themselves or as a part of the protective coatings, all of which can provide high hardness and excellent corrosion resistance.

According to the results of the corrosion resistance evaluation by salt spray test, the Cr—Zr—N alloy coatings (Examples 1 to 12) provided by the present disclosure all can introduce excellent corrosion resistance to the substrates. The Cr—Zr—N alloy coatings provided by the present disclosure in Examples 1 to 5 and 8 to 12 are single-layer film structures, and can directly provide surface protection for the substrate. The Cr—Zr—N alloy coating provided by the present disclosure in Example 6 is a double-layer film structure, and acts as a lower protective layer. The surface layer (TiN coating) is further coated on the surface of the Cr—Zr—N alloy coating away from the substrate, and the TiN coating acts as the surface decorative coating (the upper layer). The Cr—Zr—N alloy coating in Example 7 is a three-layer film structure, including the transition layer (as the bottom coating), the Cr—Zr—N alloy coating, and the TiN coating in sequence from the surface of the substrate. The Cr—Zr—N alloy coating in Example 11 contains a certain atomic proportion of the doping element (≤5 at %). The elemental composition in Example 12 does not conform to a combination of the following formulas: 64.5-y≤x≤93.8-y, and 15.0≤x≤1.93y-23.4.

In Examples 1 to 7 and 9 to 11 adopting both the aluminum alloy substrates and the stainless-steel substrates, the Cr—Zr—N alloy coatings on the surfaces of the aluminum alloy substrates can pass the 48-hour salt spray corrosion resistance test, and the Cr—Zr—N alloy coatings on the surfaces of the stainless-steel substrates can pass the 144-hour salt spray corrosion resistance test. In Example 8 adopting the copper substrate, copper is more active as compared to aluminum alloy, and the Cr—Zr—N alloy coating on the surface of the copper substrate can pass the 12-hour salt spray corrosion resistance test. In Example 12, the Cr—Zr—N alloy coating on the surface of the aluminum alloy substrate can pass the 24-hour salt spray corrosion resistance test (but fails to pass the 48-hour test) and the Cr—Zr—N alloy coating on the surface of the stainless-steel substrate can pass the 96-hour salt spray corrosion resistance test (but fails to pass the 144-hour test).

The alloy coating provided by the present disclosure can be independently used as a single-layer film, or can be located in a multi-layer composite film, for example, as one layer, i.e., as the surface layer (bare), as the bottom coating (in contact with the substrate), or as the intermediate layer (located between the bottom coating and the surface layer).

According to the XRD test and the SAED test results, for the Cr—Zr—N alloy coatings (Examples 1 to 12) provided by the present disclosure, the XRD diffraction patterns each has at least one wide peak in the diffraction angle 2θ (°) range from 30° to 50° (further, all the peaks are wide peaks with the FWHM of greater than or equal to 2°). The radial intensity profiles of the SAED patterns each has at least one wide peak in the range from 2.0 Å to 3.0 Å (further, all the peaks are wide peaks with the FWHM of greater than or equal to 2°). The Cr—Zr—N alloy coatings in all examples have “highly disordered and sufficiently densely packed” atomic arrangements, which are consistent with the highly compact structures in the SEM morphology characterization results.

In addition, when the Cr—Zr—N alloy coatings provided by the present disclosure are located on the surfaces of the protective coatings (Examples 1 to 5 and 8 to 12), they can also improve the brightness of the corresponding coated articles.

The substrate bare sheets of Comparative Examples 9 to 11 are not resistant to the salt spray corrosion without the protective coating, and significant corrosion occurs within 12 hours.

The alloy coating film in Comparative Example 1 lacks element N, the alloy coating films in Comparative Examples 2 and 4 have relatively high content of element N, and the Cr—Zr—N alloy coating is not provided in Comparative Example 3 (a TiN coating is provided in Comparative Example 3). The results show that all coatings in Comparative Examples 1 to 4 fail to pass the corrosion resistance testing (NG).

The hardness and corrosion resistance of the alloy coatings with different thicknesses prepared in Comparative Examples 5 to 8 are significantly inferior to those of the Cr—Zr—N alloy coatings of the present disclosure with the corresponding same thicknesses. The thickness as high as 6000 nm (6 microns) is used in Comparative Example 8, and even though the hardness is relatively high, the corrosion resistance is still poor. It is speculated that the reason may be that: the film structure is not dense and includes gaps, such as penetrating columnar gaps, causing the corrosion solution to quickly come into contact with the substrate through the gaps, thereby leading to the corrosion resistance failure of the coating. Although increasing the thickness of the coating can increase the hardness of the coating, structural defects still exist. In contrast, the Cr—Zr—N alloy coating provided by the present disclosure can have both high hardness and excellent corrosion resistance even with a relative thin thickness, thereby saving raw materials, simplifying processes, shortening production cycles, and significantly reducing costs. When the alloy coatings are relatively thin, the formed coated articles can show a silver-white metal color, which is close to the metal color of the substrates, being conducive to achieving a beautiful decorative effect without changing the color of the substrates.

The technical features in the above-mentioned embodiments or examples can be combined arbitrarily. In order to make the description concise, not all possible combinations of the technical features in the above-mentioned embodiments or examples are described. However, as long as there is no contradiction in the combination of these technical features, the combinations should be considered as in the scope of the present disclosure.

The above-described embodiments or examples are only several implementations of the present disclosure in order to understand the technical solutions of the present disclosure in detail, but they should not be construed as limiting the scope of the present disclosure. It should be understood by those of ordinary skill in the art that various modifications and improvements can be made without departing from the concept of the present disclosure, and all fall within the protection scope of the present disclosure. In addition, it should be understood that after reading the above teachings of the present disclosure, those skilled in the art can make various changes or modifications to the present disclosure, and the obtained equivalent forms also fall within the scope of the present disclosure. It should also be understood that technical solutions obtained by those skilled in the art through logical analysis, reasoning or limited experiments on the basis of the technical solutions according to the present disclosure are within the scope of the claims appended to the present disclosure. Therefore, the protection scope of the present disclosure shall be based on the contents of the appended claims, and the specification and drawings can be used to explain the contents of the claims.

1-20. (canceled)

21. A zirconium-rich Cr—Zr—N alloy coating, comprising a Cr—Zr—N alloy material, wherein the Cr—Zr—N alloy material is represented by a chemical formula of (CrₓZr_{y}N_{z})Mₐ, where M is a doping element, x, y, z, and a are each independently an atomic proportion, 15.0≤x≤53.8, 30.0≤y≤78.8,6.2≤z≤35.5,and 0≤a/(x+y+z+a)≤0.05.

22. The Cr—Zr—N alloy coating according to claim 21, wherein 64.5-y≤x≤93.8-y, and 15.0≤x≤1.93y-23.4.

23. The Cr—Zr—N alloy coating according to claim 21, wherein 15.0≤x≤53.8, 33.7≤y≤78.8, and 6.2≤z<28.0.

24. The Cr—Zr—N alloy coating according to claim 23, wherein 72-y<x≤93.8-y, and 15.0≤x<2.5y-44.6.

25. The Cr—Zr—N alloy coating according to claim 21, wherein a sum of x, y, and z is 100.

26. The Cr—Zr—N alloy coating according to claim 21, wherein the Cr—Zr—N alloy coating satisfies two features as follows:
an X-ray diffraction (XRD) pattern of the Cr—Zr—N alloy material or the Cr—Zr—N alloy coating has one or more peaks in a diffraction angle 2θ (°) range from 30° to 50°, and a full width at half maximum (FWHM) of at least one 2θ (°) diffraction peak in the range from 30° to 50° is greater than or equal to 2°; and
a radial intensity profile corresponding to a selected area electron diffraction (SAED) pattern of the Cr—Zr—N alloy material or the Cr—Zr—N alloy coating, with characteristic interatomic spacing as a horizontal axis and diffraction intensity as a vertical axis, has one or more diffraction peaks in a range from 2.0 Å to 3.0 Å, and a FWHM of at least one of the diffraction peaks in the range from 2.0 Å to 3.0 Å is greater than or equal to 0.21 Å.

27. The Cr—Zr—N alloy coating according to claim 21, wherein a thickness of the Cr—Zr—N alloy coating is in a range from dₘᵢₙ to 6 μm, dₘᵢₙ being a value selected from 10 nm to 50 nm.

28. The Cr—Zr—N alloy coating according to claim 27, wherein dₘᵢₙ is 10 nm, 20 nm, 25 nm, 30 nm, 40 nm, or 50 nm.

29. The Cr—Zr—N alloy coating according to claim 21, wherein the doping element is a non-metal element, a metal element, or a combination thereof;
the non-metal element comprises O, C, B, Si, Ar, or any combination thereof; and
the metal element comprises Ti, V, Nb, Mo, Hf, Ta, W, Ni, Mo, Fe, Ag, Au, Cu, Al, or any combination thereof.

30. The Cr—Zr—N alloy coating according to claim 21, wherein 0≤a/(x+y+z+a)≤0.02.

31. A coated article, comprising a substrate and the Cr—Zr—N alloy coating according to claim 21, wherein the Cr—Zr—N alloy coating is located on at least one side of the substrate.

32. The coated article according to claim 31, wherein a surface material of the substrate is an alloy, an elemental metal, or an inorganic non-metal material;
a material type of the alloy comprises nickel base, iron base, tungsten base, titanium base, silicon base, aluminum base, copper base, cobalt base, zirconium base, zinc base, or any combination thereof;
the elemental metal zinc, gold, platinum, zirconium, hafnium, niobium, tantalum, nickel, copper, aluminum, iron, silver, or chromium;
the inorganic non-metal material comprises ceramic, glass, or a combination thereof.

33. The coated article according to claim 31, wherein the surface material of the substrate is a light alloy or a stainless-steel;
the light alloy comprises a titanium alloy, an aluminum alloy, a magnesium alloy, or any combination thereof.

34. The coated article according to claim 31, wherein the coated article satisfies one or more of following features:
the Cr—Zr—N alloy coating is in direct contact with the substrate; alternatively, a transition layer is disposed between the Cr—Zr—N alloy coating and the substrate;
the Cr—Zr—N alloy coating forms a surface of the coated article; alternatively, a surface layer is disposed on a side of the Cr—Zr—N alloy coating away from the substrate, the surface layer being a single-layer structure or a multi-layer structure.

35. A hard coating comprising the Cr—Zr—N alloy coating according to claim 21.

36. The hard coating according to claim 35, wherein the hard coating is further a corrosion-resistant coating.

37. A method for preparing a Cr—Zr—N alloy coating, comprising a step of: depositing composition elements of the Cr—Zr—N alloy coating onto at least a portion of a surface of a substrate according to a preset atomic ratio of the composition elements by vapor deposition technique, thereby forming the Cr—Zr—N alloy coating according to claim 21.

38. The method according to claim 37, wherein the Cr—Zr—N alloy coating is formed by a method comprising a step of: under a condition of introducing a mixed gas comprising argon gas and a nitrogen-containing gas, sputtering a target comprising chromium, zirconium and a combination thereof to deposit the composition elements of the Cr—Zr—N alloy coating on at least a portion of a surface of a substrate, thereby forming the Cr—Zr—N alloy coating.

39. The method according to claim 38, wherein the method satisfies one or more following features:
the sputtering deposition is performed at a temperature in a range from 30 °C to 330 °C;
a total gas-pressure of the mixed gas containing argon gas and the nitrogen-containing gas is in a range from 0.3 Pa to 1.2 Pa;
the target comprises a chromium target, and a power density for the chromium target is in a range from 1.3 W/cm² to 6.7 W/cm²;
the target comprises a zirconium target, and a power density for the zirconium target is in a range from 0.8 W/cm² to 7.9 W/cm²;
the target comprises an alloy target, the alloy target comprises at least two metal elements of the Cr—Zr—N alloy coating; and a power density for the chromium-zirconium base alloy target is in a range from 4 W/cm² to 6 W/cm²;
a bias voltage applied to the substrate is in a range from −150 V to −20 V,
the sputtering deposition is performed for 10 min to 150 min;
the nitrogen-containing gas is nitrogen gas, and a flow rate of the nitrogen gas is in a range from 8 sccm to 52 sccm; and
the nitrogen-containing gas is nitrogen gas, and a flow rate of argon gas to nitrogen gas in the mixed gas is in a range from 2:1 to 6:1.

40. A Cr—Zr—N alloy material, wherein the Cr—Zr—N alloy material is as defined in claim 21.
